(19) United States
(12) Patent Application Publication
(10) Pub. No.: US 2024/0076196 A1
(43) Pub. Date: Mar. 7, 2024

(54) PROCESS FOR PREPARING METAL OXIDE NANOSHEETS

(71) Applicant: ROYAL MELBOURNE INSTITUTE OF TECHNOLOGY, Melbourne, Victoria (AU)

(72) Inventor: Nasir MAHMOOD, Melbourne, Victoria (AU)

(21) Appl. No.: 18/261,934

(22) PCT Filed: Jan. 18, 2022
(86) PCT No.: PCT/AU2022/050022

§ 371 Date: Jul. 18, 2023

(30) Foreign Application Priority Data
Jan. 18, 2021 (AU) 2021900097

(51) Int. Cl. C01G 9/02; H10N 30/077; H10N 30/095

(52) U.S. Cl. CPC C01G 9/02; H10N 30/077; H10N 30/095; B82Y 30/00; C01P 2002/01; C01P 2002/20; C01P 2002/72; C01P 2002/85; C01P 2004/04; C01P 2004/24; C01P 2006/40

(57) ABSTRACT

The present disclosure relates generally to processes for preparing metal oxide nanosheets. In particular, the process may comprise generating a liquid metal film comprising a metal oxide surface layer, and exfoliating the metal oxide surface layer to form a metal oxide nanosheet. The present disclosure also relates generally to devices comprising the metal oxide nanosheets, such as piezoelectric generators and sensors.

### FIELD

The present disclosure relates to processes for preparing metal oxide nanosheets. In particular, the present disclosure relates to a liquid metal-based synthesis approach to prepare metal oxide nanosheets having controlled nanometer thicknesses. The present disclosure also relates to devices comprising the metal oxide nanosheets, such as piezoelectric generators or sensors.

### BACKGROUND

Two dimensional (2D) structures (e.g., sheets including nanosheets) have established new levels of functionalities for materials. In particular, two-dimensional (2D) oxides have a wide variety of applications in electronics and other technologies. However, many oxides are not easy to synthesize as 2D materials through conventional methods such as mechanical exfoliation techniques and physical/wet chemical deposition processes such as thermal evaporation assisted chemical vapour deposition, which often require sophisticated equipment, specific layered crystal precursors, expensive chemical pretreatment, and harsh and/or prolonged reaction conditions, which ultimately result in 2D sheets with variable thickness and uniformity. There is a need for alternative or improved processes which can prepare 2D metal oxide nanosheets having controlled and uniform thicknesses from simple starting materials, which are scalable for industrial application and/or provide improved performance.

It will be understood that any prior art publications referred to herein do not constitute an admission that any of these documents form part of the common general knowledge in the art, in Australia or in any other country.

### SUMMARY

The present inventors have undertaken research and development into processes for preparing metal oxide nanosheets. In particular, the present inventors have identified a liquid metal-based synthesis approach to prepare metal oxide nanosheets having controlled thicknesses that were previously inaccessible using pre-existing conventional techniques, such as mechanical exfoliation, wet chemical deposition, and chemical vapour deposition. The process described herein can be scalable for industrial application, and can provide for control, flexibility and consistency in the manufacture of metal oxide nanosheets, including nanosheets having both a large lateral area and nanometer thickness. Owing to the flexibility of the process, a variety of metal oxide nanosheets, including ultra-thin zinc oxide (ZnO) nanosheets which demonstrate exceptional piezoelectric properties, and may find utility in a variety of sensing and energy harvesting applications.

The process comprises generating a liquid metal film comprising a metal oxide surface layer. The metal oxide surface layer on the liquid metal film forms the metal oxide nanosheet layer. The metal oxide surface layer is removed from the liquid metal film to form the metal oxide nanosheet layer, for example by exfoliating the metal oxide surface layer from the liquid metal film to form the metal oxide nanosheet layer. To exfoliate the metal oxide surface layer from the liquid metal film, the metal oxide surface layer may be contacted with a target substrate. The liquid metal film is initially formed by melting a metal. The metal is heated to a temperature effective to melt the metal. The temperature may be at or above the melting temperature of the metal. The metal may be provided on a supporting substrate. The metal may be heated on the supporting substrate to generate the liquid metal film on the supporting substrate. The metal may be heated in an oxygen environment to generate a liquid metal film comprising a metal oxide surface layer. Exfoliating the metal oxide surface layer can expose fresh liquid metal film to the oxygen atmosphere to form a regenerated metal oxide surface layer. A metal oxide nanosheet may be prepared using the process described herein. A multilayered metal oxide nanosheet may be formed by contacting the regenerated metal oxide surface layer with the metal oxide nanosheet layer. The metal oxide nanosheet layer or layers may be used to prepare a piezoelectric generator or sensor comprising the metal oxide nanosheet layer or layers.

In one aspect, there is provided a process for preparing a metal oxide nanosheet, comprising the steps of:
a) heating a metal that is provided on a supporting substrate to a temperature effective to melt the metal to generate a liquid metal film on the supporting substrate,
b) contacting the liquid metal film with an oxygen atmosphere to generate a metal oxide surface layer on the liquid metal film, and
c) contacting the metal oxide surface layer with a target substrate, and exfoliating the metal oxide surface layer from the supporting substrate to form a metal oxide nanosheet layer on the target substrate.

In another aspect, there is provided metal oxide nanosheet prepared by the process defined above. In another aspect, there is provided a piezoelectric generator or sensor comprising a metal oxide nanosheet prepared by the process defined above.

It will be appreciated that any one or more of the embodiments and examples described herein for the process for preparing the metal oxide nanosheet may also apply to the metal oxide nano sheet, and/or piezoelectric generator or sensor described herein. Any embodiment herein shall be taken to apply mutatis mutandis to any other embodiment unless specifically stated. It will also be appreciated that other aspects, embodiments and examples of the process, metal oxide nanosheet and/or piezoelectric generator or sensor are described herein.

It will also be appreciated that some features of the process, metal oxide nanosheet and/or piezoelectric generator or sensor identified in some aspects, embodiments or examples as described herein may not be required in all aspects, embodiments or examples as described herein, and this specification is to be read in this context. It will also be appreciated that in the various aspects, embodiments or examples, the order of method or process steps may not be essential and may be varied.

### BRIEF DESCRIPTION OF THE DRAWINGS

Preferred embodiments of the present disclosure are further described and illustrated as follows, by way of example only, with reference to the accompanying drawings in which:

FIG. 1. Theoretical representations of (a) The PBE and (b) PBE+U structures for the 3-layer ZnO system.

FIG. 2. The 3-layer, 5-layer and 8-layer Zn—O planar structures (from left to right) before structural optimization. The shaded regions (in the light grey) show the atoms that were maintained as fixed during the geometry optimisation calculation. Grey spheres denote Zn-atoms, dark grey spheres O-atoms and black spheres Si-atoms.

FIG. 3. A representation of the optimized 3-layer, 5-layer and 8-layer Zn—O structures on the (0001) face of the α-SiO₂ substrate. Grey spheres denote Zn-atoms, dark grey spheres O-atoms and black spheres Si-atoms.

FIG. 4. Illustration of the c-axis distance between each of the Zn and O atoms within the ZnO layer. Grey spheres denote Zn-atoms, dark grey spheres O-atoms and black spheres Si-atoms.

FIG. 5. a) Theoretically calculated average Zn—O c-axis distance, d_{avg} (Zn—O) vs. number of ZnO layers (thickness in nm). b) Experimentally measured behaviour of d₃₃ values vs. ZnO sheet thickness in nm (approximate number of layers are also given).

FIG. 6. Theoretically calculated Zn—O distance in various layers, depending on the overall number of layers.

FIG. 7. Schematic illustration of synthesis set-up of 2D ZnO nanosheets, shown in a customized glove box.

FIG. 8. Synthesis, Structural and morphological characterization of ZnO: a) Schematic illustration of growth of ZnO sheets and their exfoliation. b) Optical image delineating homogenous millimetre sized ZnO sheet, scale bar is 100 μm. c) AFM images i. approximately 0.6 nm thick ZnO sheets at scale bar of 500 nm and ii. approximately 1.1 nm thick ZnO sheet at scale bar of 4 μm (the insets show thickness profiles). d) TEM image showing a folded edge to delineate the ultrathin features, scale bar is 500 nm. e) A TEM image of a thicker ZnO nanosheet, scale bar is 1 μm. f) SAED pattern indexed to (002) plane showing hexagonal ZnO. g) HRTEM image showing preferred growth direction in wurtzite phase of ZnO, scale bar is 1 nm.

FIG. 9. a) and b) AFM image and related profile of approximately 0.6 nm thick ZnO nanosheet, c) and d) AFM image and related profile of approximately 1.1 nm thick ZnO nanosheet, e) and f) AFM image and related profile of approximately 3 nm thick ZnO nanosheet and g) and h) AFM image and related profile of approximately 4 nm thick ZnO nanosheet.

FIG. 10. TEM, HRTEM and SAED of two ZnO sheets: (a) TEM image of ZnO sheet #1 (b) HRTEM image corresponding to circle marked by arrow in sheet #1 and (c, e) are zoomed area from different spots of (b) marked by boxes and (d, f) filtered HRTEM images of Figure c, e (Note: a filter is applied to clearly represent the crystal structure due to ultrathin nature of ZnO sheet and background carbon layer from TEM grid). No grain boundary is seen at any point on the sheet presented in (b). No grain boundary or defects can be seen. (g) TEM image of ZnO sheet #2, (h-k) SAED patterns from marked circles in Figures a and g. A scale bar in Figure c-f is 5 nm.

FIG. 11. a) Raman spectra excited at 532 nm showing vibration modes of large area ZnO nanosheets; b) XRD pattern of large area ZnO nanosheets versus bulk ZnO; c) High resolution XPS spectra of large area ZnO nanosheets for Zn 2p, and d) O is of ZnO nanosheets, commercial ZnO and SiO₂ substrate.

FIG. 12. The photoluminescence spectrum of approximately 1.1 nm thick ZnO sheet.

FIG. 13. XPS depth profiles of Zn 2p_{3/2} (a, b) 8-layer and (c, d) 5-layer ZnO sheets.

FIG. 14. XPS valence band yielding the energy difference between the Fermi level and the valence band maximum (VBM) of approximately 1.1 nm thick ZnO sheet.

FIG. 15. Photoelectron spectroscopy in air (PESA) spectrum measured for approximately 1.1 nm thick ZnO sheet.

FIG. 16. Tauc plot elucidating the optical bandgap of approximately 1.1 nm thick ZnO sheet.

FIG. 17. Assessed band structure of approximately 1.1 nm thick ZnO sheet evaluated by combining the PESA, valence and Tauc plot spectra.

FIG. 18. Graph showing the PR amplitude vs. the drive voltage frequency as measured on the substrate. Background frequency sweep on SiO₂/Si substrate to ensure the contact resonance frequency of imaging (325 kHz) has a low noise floor and is frequency independent. A background measurement was conducted to ensure that the frequency had a low background contribution.

FIG. 19. Statistical analysis on the amplitude difference between the ZnO sheet and the amplitude of the substrate. The two average values are subtracted to obtain the amplitude of the signal.

FIG. 20. Force curve measuring the deflection sensitivity of the conductive AFM tip used. An average value (103.3 nm/V) of 5 these measurements was used in the calculations.

FIG. 21. a) Slope showing the d₃₃ slope of 80±0.8 pm/V, which is the average variation in displacement observed with increasing driving voltage amplitude for approximately 1.1 nm thick ZnO (5 Zn—O layers in a wurtzite crystal) sheets. b) Topography of approximately 1.1 nm thick scanned sheet of ZnO. c-p) PFM amplitude plots for each driving voltage applied to the ZnO nanosheets along with the statistical distribution of amplitude values.

FIG. 22. PFM showing phase graphs for driving voltage of a) 0V, b) 2V c) 4V d) 6V applied to ZnO on approximately 1.1 nm thick sheet. (Scale bars of 4 μm).

FIG. 23. a) Topography of approximately 0.6 nm thick sheet b)-e) PFM showing amplitude graphs for each driving voltage applied to ZnO i) graph showing the d₃₃ slope of approximately 34 pm/V which is the variation in displacement with an increase in driving voltage amplitude.

FIG. 24. a) Topography of approximately 4 nm thick sheet b)-e) PFM showing amplitude graphs for each driving voltage applied to a ZnO i) graph showing the d₃₃ slope of approximately 16 pm/V which is the variation in displacement with increase in driving voltage amplitude.

FIG. 25. (a) Topography of FIG. 5 for the approximately 1.1 nm thick scanned sheet of ZnO at a rotated orientation. (b-d and f) PFM amplitude plots for the stated driving voltage applied to the ZnO nanosheet. (e) A repeated scan at 3V, at a different area indicating high stability of ZnO sheets. A scale bar is 2 μm. Note: The measurements of the new crystal orientation were conducted 16 weeks after the initial measurements for the ZnO sheet.

FIG. 26. The graph shows the d₃₃ slope of approximately 78 pm/V, which is the average variation in displacement observed with increasing driving voltage amplitude for approximately 1.1 nm thick ZnO (5 Zn—O layers in a wurtzite crystal) sheets in Figure S17. The plot also shows the value of a scan repeated at two different voltages (i.e., 3V) denoted by area 2, approx. on the same sample at a different crystal orientation as pictured in Figure S 17e) indicating high stability of the ZnO sheets. Note: the measurements of the new crystal orientation were conducted after 16 weeks of the initial measurements also showing the long-term stability of the sheets.

Table 1. Comparative summary of experimentally derived d₃₃ piezoelectric coefficients on selected 2D materials (some in comparison to their bulks), in comparison to this work.

### DETAILED DESCRIPTION

The present disclosure describes the following various non-limiting embodiments, which relate to investigations undertaken to identify processes to prepare metal oxide nanosheets. Additional non-limiting embodiments of the process, metal oxide nanosheets, sensors and applications are also described. It has been surprisingly found that the liquid-metal based process to prepare metal oxide nanosheets described herein provides one or more advantages including preparing ultra-thin (i.e., nanometre thick) metal oxide nanosheets, such as zinc oxide (ZnO) nanosheets. The thickness of the metal oxide nanosheets can be finely controlled by tailoring the reaction process conditions. In some embodiments, nanometre thick ZnO nanosheets may be prepared using the process described herein which demonstrate excellent piezoelectric properties, and find utility as sensors in a variety of industrial applications including for example biomedical and mechanical sensors and also as a piezoelectric generator which may be used in energy harvesting applications. In contrast to conventional processes which often require mechanical exfoliation of layered crystal structures or chemical vapour deposition which requires thermal evaporation of metal powders/precursors, the present disclosure uses a liquid-metal based process to prepare metal oxide nanosheets at the metal-melt/air interface. This process can prepare metal oxide nanosheets significantly faster than conventional techniques whilst finely controlling the nanosheet thickness and uniformity. Other applications and advantages associated with the liquid-metal based process are also described herein.

### Terms

In the following description, reference is made to the accompanying drawings which form a part hereof, and which is shown, by way of illustration, several embodiments. It is understood that other embodiments may be utilized and structural changes may be made without departing from the scope of the present disclosure.

With regards to the definitions provided herein, unless stated otherwise, or implicit from context, the defined terms and phrases include the provided meanings. Unless explicitly stated otherwise, or apparent from context, the terms and phrases below do not exclude the meaning that the term or phrase has acquired by a person skilled in the relevant art. The definitions are provided to aid in describing particular embodiments, and are not intended to limit the claimed invention, because the scope of the invention is limited only by the claims. Furthermore, unless otherwise required by context, singular terms shall include pluralities and plural terms shall include the singular.

All publications discussed and/or referenced herein are incorporated herein in their entirety.

Any discussion of documents, acts, compositions, processes, materials, devices, articles or the like which has been included in the present specification is solely for the purpose of providing a context for the present disclosure. It is not to be taken as an admission that any or all of these matters form part of the prior art base or were common general knowledge in the field relevant to the present disclosure as it existed before the priority date of each claim of this application.

Throughout this disclosure, unless specifically stated otherwise or the context requires otherwise, reference to a single step, composition of matter, group of steps or group of compositions of matter shall be taken to encompass one and a plurality (i.e., one or more) of those steps, compositions of matter, groups of steps or groups of compositions of matter. Thus, as used herein, the singular forms “a”, “an” and “the” include plural aspects unless the context clearly dictates otherwise. For example, reference to “a” includes a single as well as two or more; reference to “an” includes a single as well as two or more; reference to “the” includes a single as well as two or more and so forth.

Those skilled in the art will appreciate that the disclosure herein is susceptible to variations and modifications other than those specifically described. It is to be understood that the disclosure includes all such variations and modifications. The disclosure also includes all of the examples, steps, features, methods, compositions, coatings, processes, and coated substrates, referred to or indicated in this specification, individually or collectively, and any and all combinations or any two or more of said steps or features.

The term “and/or”, e.g., “X and/or Y” shall be understood to mean either “X and Y” or “X or Y” and shall be taken to provide explicit support for both meanings or for either meaning.

Unless otherwise indicated, the terms “first,” “second,” etc. are used herein merely as labels, and are not intended to impose ordinal, positional, or hierarchical requirements on the items to which these terms refer. Moreover, reference to a “second” item does not require or preclude the existence of lower-numbered item (e.g., a “first” item) and/or a higher-numbered item (e.g., a “third” item).

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example and without limitation, two of item A, one of item B, and ten of item C; four of item B and seven of item C; or some other suitable combination.

As used herein, the term “about”, unless stated to the contrary, typically refers to a range of up to +/−10% of the designated value, and includes smaller ranges therein, for example +/−5%, or +/−1% of the designated value.

It is to be appreciated that certain features that are, for clarity, described herein in the context of separate embodiments, may also be provided in combination in a single embodiment. Conversely, various features that are, for brevity, described in the context of a single embodiment, may also be provided separately or in any sub-combination.

Throughout the present specification, various aspects and components of the invention can be presented in a range format. The range format is included for convenience and should not be interpreted as an inflexible limitation on the scope of the invention. Accordingly, the description of a range should be considered to have specifically disclosed all the possible sub-ranges as well as individual numerical values within that range, unless specifically indicated. For example, description of a range such as from 1 to 5 should be considered to have specifically disclosed sub-ranges such as from 1 to 3, from 1 to 4, from 1 to 5, from 2 to 4, from 2 to 5, from 3 to 5 etc., as well as individual and partial numbers within the recited range, for example, 1, 2, 3, 4, 4.5, 4.75, and 5, unless where integers are required or implicit from context. This applies regardless of the breadth of the disclosed range. Where specific values are required, these will be indicated in the specification.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

The reference to “substantially free” generally refers to the absence of that compound or component in a composition, for example in the liquid metal film or metal oxide nanosheet layer, other than any trace amounts or impurities that may be present, for example this may be an amount by weight % in the composition of less than about 1%, 0.1%, 0.01%, 0.001%, or 0.0001%. The compositions as described herein, for example the liquid metal film or metal oxide nanosheet layer, may also include, for example, impurities in an amount by weight % in the total composition of less than about 5%, 4%, 3%, 2%, 1%, 0.5%, 0.1%, 0.01%, 0.001%, or 0.0001%.

### Process for Preparing Metal Oxide Nanosheets.

One main goal of the process for preparing the metal oxide nanosheets described herein was to establish process conditions that can be used to prepare large lateral area yet ultra-thin nanosheets. By finely controlling the thickness of the metal oxide nanosheets, various properties not present in their bulk counterparts can be exploited and in some cases enhanced, including piezoelectric properties.

The metal oxide nanosheets described are prepared using a liquid metal-based synthesis approach which results in nanosheets that can have large lateral areas and ultra-thin (i.e., sub nanometre) thicknesses. The liquid-metal based approach uses a liquid metal film to form the metal oxide nanosheet. It will be appreciated that the liquid metal film (e.g., liquid metal droplet) does not comprise any layered crystal structure morphology i.e. has liquid properties, is fluid and is not crystalline. In contrast, conventional processes currently used to prepare 2D nanomaterials such as nanosheets top-include mechanical exfoliation of layered or stratified crystalline precursor materials (e.g. metal coordination polymers) which are essentially dissembled into smaller units (e.g. top down processes), or chemical vapour deposition which requires the thermal evaporation of metal powders/precursors (e.g. bottom up processes).

The process for preparing a metal oxide nanosheet, comprising the steps of:
a) heating a metal that is provided on a supporting substrate to a temperature effective to melt the metal to generate a liquid metal film on the supporting substrate,
b) contacting the liquid metal film with an oxygen atmosphere to generate a metal oxide surface layer on the liquid metal film, and
c) contacting the metal oxide surface layer with a target substrate, and exfoliating the metal oxide surface layer from the supporting substrate to form a metal oxide nanosheet layer on the target substrate.

### Metal and Liquid Metal Film

The liquid metal film may be prepared by heating a suitable metal to a temperature effective to melt the metal to generate the liquid metal film. Any reference to “liquid” in relation to the liquid metal film refers to the metal being substantially liquid (i.e. melted), for example to essentially exclude substantially solid particles. It will be appreciated that a “liquid” metal film may comprise a small portion of unmelted metal whilst being overall a liquid. In other words, the term “liquid” metal film may comprise a small amount of solid material, for example less than about 1%, 0.1%, 0.01%, 0.001%, or 0.0001% of the liquid. A liquid may also be substantially devoid of any layer/stratified or crystalline morphology.

Any metal capable of forming a metal oxide upon exposure to oxygen may be used to prepare the liquid metal film. The metal may be a transition metal, post-transition metal, metalloid, or rare earth metal (including actinides and lanthanides). In one embodiment, the metal may be a transition metal. In one embodiment, the transition metal may be selected from, iron, cobalt, nickel, zinc. Other metals may also be suitable as understood by the person skilled in the art. In one embodiment, the metal may comprise or consist of zinc (Zn) metal. The zinc metal may have a purity of at least 90, 95, 99, 99.5, 99.7 or 99.8% purity.

In one embodiment, the process may comprise melting a single metal. In this embodiment, the process may be referred to as a single metal system as opposed to a mixed metal system, and the metal is not a mixture of metals (e.g., an alloy) but rather consists of a single metal, such as zinc (Zn) metal. According to at least some embodiments or examples described herein, such a single metal system results in a homogeneous liquid metal film following heating, which allows for the formation of the corresponding metal oxide surface layer on the film's surface in a competitive reaction-free environment following contact with an oxygen environment. In contrast, where metal mixtures (such as alloys) are heated, the resulting metal oxide on the surface following oxidation is determined by the reactivity of the individual metals within the alloy melt and thus limited to the metal oxide that results in the greatest reduction of Gibbs free energy that will dominate the at the surface. Thus, a single metal system described herein can therefore offer one or more advantages, including versatility and ease of synthesis of a variety of different type of metal oxides and is not constrained or restricted by having multiple competing metals present in the liquid metal film. In one embodiment, the metal is not an alloy, for example is not a gallium-based alloy. In a further embodiment, the liquid metal film is substantially free of gallium, indium and/or tin.

The metal is heated to a temperature effective to melt the metal to generate the liquid metal film. The temperature may be selected depending on the metal, and in some embodiments, the temperature is at or above the melting point of the metal. In one embodiment, the metal is heated to a temperature above the melting point of the metal. In some embodiments, the metal is heated to a temperature of at least about 200, 250, 300, 350, 400, 450, 500, 550, 600, 650, or 700° C. In some embodiments, the metal is heated to a temperature of less than about 700, 650, 600, 550, 500, 450, 400, 350, 300, 250, or 200° C. In some embodiments, the metal is heated to a temperature of at least about 300, 320, 340, 360, 380, 400, 420, 440, 460, 480, 500, 520, 540, 560, 580 or 600° C. In some embodiments, the metal is heated to a temperature of less than about 600, 580, 560, 540, 520, 500, 480, 460, 440, 420, 400, 380, 360, 340, 320, or 300° C. Combinations of any two of these upper and/or lower temperatures can provide a range selection, for example between about 200° C. to about 700° C., between about 300° C. to about 600° C. In one embodiment, the metal is heated at a temperature of about 500° C. In other embodiments, depending on the target metal used to prepare the metal oxide, the metal may be heated to a temperature higher than 700° C., and for example may be at least about 1000, 1050, 1100, 1150, 1200, 1250, 1300, 1450, 1500, 1550, 1600, 1650, 1700, 1750 or 1800° C., including any range selection provided by any two of these temperature values. In one embodiment, the metal is heated to a temperature of greater than 200° C. but less than the melting temperature of the supporting substrate.

The heating may be provided by any suitable means, including an oven (e.g. electric furnace) or a hotplate, for example housed in a reaction chamber.

In one embodiment, the metal may be heated in an inert atmosphere (i.e. oxygen free environment) to form the liquid metal film. In this embodiment, the liquid metal film is subsequently contacted with the oxygen atmosphere to generate the metal oxide surface layer on the liquid metal film. The inert atmosphere may be selected from nitrogen, argon, or helium, for example nitrogen.

In another embodiment, the metal is heated in the oxygen atmosphere and the metal oxide surface layer is generated in-situ on the liquid metal film. Accordingly, in one aspect or embodiment, there is provided a process for preparing a metal oxide nanosheet, comprising the steps of heating a metal that is provided on a supporting substrate in an oxygen atmosphere to a temperature effective to melt the metal to generate a liquid metal film comprising a metal oxide surface layer on the supporting substrate, and contacting the metal oxide surface layer with a target substrate, and exfoliating the metal oxide surface layer from the supporting substrate to form a metal oxide nanosheet layer on the target substrate. It will be appreciated that in this aspect or embodiment, steps a) and b) described herein occur simultaneously (i.e. in-situ formation of the metal oxide surface layer).

In one embodiment, the metal is heated on a supporting substrate. The supporting substrate is defined below. The supporting substrate provides a surface to support the metal during heating and in turn supports the generated liquid metal film. In some embodiments, the supporting substrate is heated a temperature effective to melt the metal to form the liquid metal film on the supporting substrate. The supporting substrate may be heated by being placed on a heater or hotplate, or in an oven. In one embodiment, the supporting substrate is heated on a hotplate. In one embodiment, the supporting substrate is heated on a hotplate in an enclosed reaction chamber, such as a glove box.

The supporting substrate may be heated to a temperature at or above the melting point of the metal, but lower than the melting point of the substrate. In some embodiments, the supporting substrate is heated to a temperature of at least about 200, 250, 300, 350, 400, 450, 500, 550, 600, 650, or 700° C. In some embodiments, the supporting substrate is heated to a temperature of less than about 700, 650, 600, 550, 500, 450, 400, 350, 300, 250, or 200° C. In some embodiments, the supporting substrate is heated to a temperature of at least about 300, 320, 340, 360, 380, 400, 420, 440, 460, 480, 500, 520, 540, 560, 580 or 600° C. In some embodiments, the supporting substrate is heated to a temperature of less than about 600, 580, 560, 540, 520, 500, 480, 460, 420, 400, 380, 360, 340, 320, or 300° C. Combinations of any two of these upper and/or lower temperatures can provide a range selection, for example between about 200° C. to about 700° C., between about 300° C. to about 600° C. In one embodiment, the supporting substrate is heated to about 500° C. In other embodiments, depending on the target metal used to prepare the metal oxide, the supporting substrate may be heated to a temperature higher than 700° C., and for example at least about 1000, 1050, 1100, 1150, 1200, 1250, 1300, 1450, 1500, 1550, 1600, 1650, 1700, 1750 or 1800° C., including any range selection provided by any two of these temperature values.

The heating temperature has surprisingly been found to aid in the interfacial reaction between the liquid metal surface and the oxygen atmosphere. According to at least some embodiments or examples, zinc metal heated to a temperature above its melting point has been surprisingly form a liquid zinc metal film comprising a uniform thick zinc oxide surface layer on the liquid zinc metal film. In one embodiment, the zinc metal is heated to a temperature of at least 420, 430, 440, 450, 460, 470, 480, 590, 600, 610, 620, 630, 640, 650, 660, 670, 680, 690, or 700° C. Combinations of any two of these upper and/or lower temperatures can provide a range selection, for example between about 420° C. to about 600° C., e.g. about 500° C. The skilled person will be readily able to determine the melting point of other metals and select a temperature that is at or above the respective melting points. If the selected metal is capable of forming more than one oxide (e.g. iron), the temperature has also been found to preferentially form one oxide phase over others. The skilled person is able to readily determine the heating temperature to preferentially form a specific metal oxide phase based on the properties of the selected metal.

The heating of the metal may be for a suitable period of time to melt the metal to generate the liquid metal film. In some embodiments, the heating of the metal may be for a period of time of at least about 1, 2, 5, 10, 15, 20, 30, 40, 50, 60, 90, 120, or 180 seconds. In some embodiments, the heating of the metal may be for a period of time of less than 180, 120, 90, 60, 50, 40, 30, 20, 15, 10, 5, 2 or 1 second. Combinations of any two of these upper and/or lower times can provide a range selection, for example between about 10 seconds to about 120 seconds.

### Supporting Substrate

The metal is provided on a supporting substrate. The supporting substrate provides a surface to support the metal during heating and in turn supports the generated liquid metal film. The supporting substrate may comprise or consist of an inert material which does not react with the metal or the liquid metal film. In some embodiments, the supporting substrate does not form a bond (e.g. covalent bond) with the liquid metal film.

In some embodiments, the supporting substrate may comprise a non-polar surface. The supporting substrate may be selected from the group consisting of glass, quartz, silicon, and indium tin oxide (ITO). In one embodiment, the supporting substrate is glass.

The supporting substrate may be selected to provide a contact angle (0) with the liquid metal film. The contact angle is the angle where the metal liquid film-atmosphere (e.g., oxygen) interface meets the surface of the supporting substrate, and quantifies the wettability of the surface of the supporting substrate by the liquid metal film via the Young equation below:

In some embodiments, the supporting substrate provides a contact angle with the liquid metal film of at least 10, 20, 30, 40, 50, 60, 70, 80, 90, 100, 110, 120, 130, 140, 150, 160, or 170°. In some embodiments, the supporting substrate provides a contact angle with the liquid metal film of less than 170, 160, 150, 140, 130, 120, 110, 100, 90, 80, 70, 60, 50, 40, 30, 20 or 10°. Combinations of any two of these upper and/or lower contact angles can provide a range selection, for example between about 20° to about 160°, between about 40° to about 140° or between about 80° to about 120° In one embodiment, the supporting substrate provides a contact angle with the liquid metal film of at least 90°. In one embodiment, the supporting substrate provides for the formation of a liquid metal droplet on the supporting substrate. The surface of the supporting substrate may be hydrophobic or hydrophilic. In one embodiment, the surface of the supporting substrate is hydrophobic.

The liquid metal film may be a layer on the supporting substrate. The liquid metal film may be a portion of a liquid metal droplet. It will be appreciated that the morphology of the liquid metal droplet may vary depending on the nature of the supporting substrate. For example, the liquid metal droplet may be substantially spherical if the supporting substrate provides a contact angle with the liquid metal droplet of greater than 90°, for example greater than 120° but less than 180°. According to some embodiments or examples, the contact angle is between about 90° to about 180° which advantageously provides a droplet with a large exposed surface area to maximize the final lateral size of the nanosheet. In contrast, if the supporting substrate provides a contact angle with the liquid metal film of less than 90°, for example less than 60°, the liquid metal film provides greater wetting of the supporting substrate and results in the formation of a liquid metal layer (e.g. a melt layer) on the supporting substrate as opposed to droplets. Thus it will be appreciated that the liquid metal film is not intended to be limited to any one morphology and includes, for example, droplets and layers. In one embodiment, the liquid metal film is a droplet or a layer.

The liquid metal film (e.g. droplet or layer) may have an average diameter. The average diameter of the liquid metal film is taken to be the cross-sectional diameter across the film. For non-spherical films (e.g. non-droplet morphologies), the diameter is taken to be the distance corresponding to the longest cross-section dimension across the film. In some embodiments, the liquid metal film has an average diameter of at least 0.1, 0.2, 0.3, 0.4, 0.5, 0.6, 0.7, 0.8, 0.9, 1, 1.1, 1.2, 1.3, 1.4, 1.5, 1.6, 1.7, 1.8, 2, 2.5, 3, 4, 5, 6, 7, 8, 9 or 10 cm. In some embodiments, the liquid metal film has an average diameter of less than 10, 9, 8, 7, 6, 5, 4, 3, 2.5, 2, 1.8, 1.7, 1.6, 1.5, 1.4, 1.3, 1.2, 1.1, 1, 0.9, 0.8, 0.7, 0.6, 0.5, 0.4, 0.3, 0.2 or 0.1 cm. Combinations of any two of these upper and/or lower film sizes can provide a range selection, for example between about 0.1 cm to about 10 cm, between about 0.2 cm to about 5 cm, or between about 0.5 cm to about 2 cm. In one embodiment, the liquid metal film has an average diameter of about 1 cm. The average size of the liquid metal film can be measured by any conventional method, including visually with a suitable measuring instrument (e.g., a ruler), optical microscopy or small angle X-ray scattering (SAXS). The inventors have identified that exfoliating the metal oxide surface layer off smaller liquid metal films (e.g., between about 0.1 cm to 2 cm in diameter) can minimise the delamination of liquid metal from the interior of the liquid metal film, thereby minimising thickness variation across the metal oxide nanosheet.

It will be appreciated that, in some embodiments, the size of the liquid metal film (e.g. droplet or layer) on the supporting substrate controls the final lateral size of the metal oxide nanosheet. By varying the liquid metal film dimensions on the supporting substrate, metal oxide nanosheets with tailored lateral size dimensions can be prepared, highlighting the flexible and versatile nature of the process.

### Metal Oxide Surface Layer and Oxygen Atmosphere

The liquid metal film is contacted with an oxygen atmosphere to form a metal oxide surface layer on the liquid metal film.

In one embodiment, the metal may be heated in the oxygen atmosphere to generate a liquid metal film comprising the metal surface layer. By heating the metal in an oxygen atmosphere, the generated liquid metal film forms a metal oxide surface layer in-situ on the liquid metal film upon contact with oxygen. Alternatively, the metal may be heated in an inert atmosphere (i.e. oxygen free environment) to form the liquid metal film, which is subsequently contacted with the oxygen atmosphere to generate the metal oxide surface layer on the liquid metal film (i.e. ex-situ formation of the metal oxide surface layer). It will be appreciated that in either of the above embodiments, the liquid metal film is contacted with the oxygen atmosphere to generate the metal oxide surface layer, as per step b).

The thickness of the metal oxide surface layer may be controlled by the oxygen atmosphere and/or the size (e.g. diameter) of the liquid metal film. In some embodiments, the metal oxide surface layer is formed at the liquid metal film-air interface. The metal oxide surface layer may be formed according to a self-limiting Cabrera-Mott reaction at the liquid metal film-air interface which results in the formation of the metal oxide surface layer on the liquid metal film. This metal oxide surface layer may be called an interfacial layer. The term “interfacial” layer refers to layer whose properties of matter are different from the values in the adjoining bulk phases. For example, the metal oxide surface layer has different properties compared to the adjoining liquid metal interior and oxygen atmosphere, thereby forming an interfacial layer. The interfacial layer adheres to the target substrate to form the metal oxide nano sheet layer.

Following oxidation in the oxygen atmosphere (either in-situ or ex-situ as described herein), the thin liquid metal film may be converted entirely to the metal oxide surface layer (i.e. metal oxide surface layer becomes a metal oxide film). Alternatively, following oxidation in the oxygen atmosphere, larger liquid metal films (e.g. liquid metal droplets) may form a metal oxide surface layer on the surface of the metal liquid film on the surface of the liquid metal film. For example, the liquid metal film may comprise a metal oxide surface layer and an inner liquid metal “core” that has not oxidised. Referring by way of example to a liquid metal droplet, following oxidation, a metal oxide surface layer may form on the surface of the droplet forming a “core-shell” structure comprising a liquid metal core and outer metal oxide shell layer.

The process may be performed entirely in the oxygen atmosphere (e.g., in-situ formation of the metal oxide surface layer). Alternatively, the melting of the metal in step a) may be performed in an inert atmosphere to form the liquid metal film, followed by introducing an oxygen atmosphere to contact with the surface of the liquid metal film to generate the metal oxide surface layer (i.e., ex-situ formation of the metal oxide surface layer).

In one embodiment, the oxygen atmosphere is ambient air. However, the inventors have identified that ultra-thin nanometre thick metal oxide nanosheets can be prepared when using a controlled oxygen atmosphere. In one embodiment, the oxygen atmosphere is a controlled oxygen atmosphere. The term “controlled” oxygen atmosphere refers to an atmosphere where the amount of oxygen present is controlled. By controlling the oxygen atmosphere, the degree of oxidation of the liquid metal film can be tailored which provides additional advantages such as controlling the thickness of the metal oxide surface layer that forms on the liquid metal film.

In one embodiment, the oxygen atmosphere is a controlled oxygen atmosphere provided by an enclosed reaction chamber comprising one or more inlets and one or more outlets, wherein a continuous flow of the oxygen atmosphere flows through at least one inlet and exits through at least one outlet to provide the controlled oxygen atmosphere. The enclosed reaction chamber may be a glove-box chamber. The enclosed reaction chamber may be a glove-box chamber. The enclosed reaction chamber may initially be charged an inert atmosphere (i.e. an oxygen free environment), for example when melting the metal to form the liquid metal film, prior to introduction of the controlled oxygen atmosphere to generate the metal oxide surface layer on the liquid metal film, as described above. In one embodiment, steps a) to c) are performed in the controlled oxygen atmosphere to generate the metal oxide surface layer on the liquid metal film in situ.

The controlled oxygen atmosphere may comprise an inert carrier gas and oxygen. The inert carrier gas does not react with the liquid metal film and acts as a carrier gas for the oxygen. In some embodiments, the controlled oxygen environment may have an oxygen concentration of at least about 0.1, 0.2, 0.5, 0.8, 1, 1.2, 1.5, 1.8, 2, 2.2, 2.5, 2.8, 3, 3.5, 4, 5, 7 or 10 vol. %, being the ratio between oxygen and the inert carrier gas. In some embodiments, the controlled oxygen environment may have an oxygen concentration of less than about 10, 7, 5, 4, 3.5, 3, 2.8, 2.5, 2.2, 2, 1.8, 1.5, 1.2, 1, 0.08, 0.5, 0.2 or 0.1 vol. %. Combinations of any two of these upper and/or lower vol. % can provide a range selection, for example between about 0.1 vol. % to about 10 vol. %, between about 0.1 vol. % to about 5 vol. %, or between about 0.1 vol. % to about 2 vol. %. In particular, the inventors have identified that an oxygen environment comprising less than 2% oxygen could yield an ultra-thin metal oxide surface layer (and in an ultra-thin metal oxide nanosheet following exfoliation). In contrast, ambient oxygen environments (such as air) may provide for thicker nanosheets. In some embodiments, the inert carrier gas is selected from nitrogen, argon, or helium, for example nitrogen.

In some embodiments, the controlled oxygen atmosphere may have an oxygen concentration of at least 1,000, 2,000, 5,000, 8,000, 10,000, 12,000, 15,000, 18,000, 20,000, 22,000, 25,000, 28,000, 30,000, 35,000, 40,000, 50,000, 70,000 or 100,000, parts per million (ppm). In some embodiments, the controlled oxygen atmosphere may have an oxygen concentration of less than about 100,000, 70,000, 50,000, 40,000, 35,000, 30,000, 28,000, 25,000, 22,000, 20,000, 18,000, 15,000, 12,000, 10,000, 8,000, 5,000, 2,000 or 1,000 ppm. Combinations of any two of these upper and/or lower ppm concentrations can provide a range selection, for example between about 1,000 ppm to about 100,000 ppm, or between about 1,000 ppm to about 20,000 ppm, e.g. less than about 20,000 ppm.

In some embodiments, the oxygen atmosphere has no flow rate, e.g. 0 standard cubic centimetres per minute (sccm), for example the process is performed in ambient air. In some embodiments, the oxygen atmosphere has a flow rate (for example when the reaction is performed in an enclosed reaction chamber such as a glove box) of at least about 100, 500, 1000, 10,000 or 100,000 sccm. In some embodiments, the oxygen atmosphere has a flow rate of less than 100,000, 10,000, 1000, 500 or 100 sccm. Combinations of any two of these upper and/or lower flow rates can provide a range selection, for example between, between about 100 sccm to about 100,000 sccm, or between about 10,000 sccm to about 100,000 sccm. It will be appreciated that the unit sccm can also be referred to as cm³/min.

In some embodiments, increasing the flow rate of the oxygen atmosphere as it contacts the liquid metal film leads to a faster rate of metal oxide surface layer formation on the liquid metal film and/or a thicker metal oxide surface layer on the liquid metal film.

The metal oxide surface layer forms a layer on the liquid metal film following contact with the oxygen atmosphere. In some embodiments or examples, the metal oxide surface layer generated upon exposure to the oxygen atmosphere is a solid layer (i.e. forms a shell on the liquid metal film). In one embodiment, the metal oxide surface layer is a metal oxide solid surface layer. The metal oxide surface layer may be crystalline. As used herein, the term “solid” layer refers to the surface layer being substantially solid, for example to essentially exclude a liquid layer. For example, upon exposure to the oxygen atmosphere, the metal oxide surface layer generated essentially forms a solid “skin” or “shell” layer on the surface of the liquid metal. By forming this solid “skin” or “shell” layer, it is easily exfoliated and separated off the metal liquid film as a solid layer, leaving the liquid metal on the supporting substrate, resulting in substantially uniform thicknesses across the metal oxide nanosheets.

Additionally, the solid properties of the metal oxide surface layer result in various advantages, including the formation of the metal oxide nanosheet on the surface of the target substrate, without the need for any forced external cooling or crystallizing step to convert a liquid non-crystalline layer into the nanosheet. In contrast, if the present solid metal oxide surface layer was force cooled upon exfoliation to the target substrate, the resulting nanosheet may comprise one or more polycrystalline defects and even generate cracks across the surface. In contrast, by not force cooling the metal oxide surface layer on exfoliation, a homogenous large lateral area crystalline nanosheets can be prepared.

It will be appreciated that the metal oxide surface layer is an oxide of the metal from the metal liquid film, i.e. the metal of the metal oxide and the liquid metal film is the same (e.g. zinc oxide surface layer on liquid metal zinc).

The metal oxide surface layer on the liquid metal film may have a suitable thickness, which can be controlled depending on the degree of oxidation in the oxygen atmosphere. In some embodiments, the metal oxide surface layer may have a thickness of at least 0.1, 0.2, 0.3, 0.4, 0.5, 0.6, 0.7, 0.8, 0.9, 1, 2, 3, 4, 5, 6, 7, 8, 9, 10, 12, 14, 16, 18, 20, 40, 80, 100, 200, 300, 400, 500, 600, 700, 800 or 1000 nm. In some embodiments, the metal oxide surface layer may have thickness of less than 1000, 900, 800, 700, 600, 500, 200, 100, 80, 40, 20, 18, 16, 14, 12, 10, 9, 8, 7, 6, 5, 4, 3, 2, 1, 0.9, 0.8, 0.7, 0.6, 0.5, 0.4, 0.3, 0.2 or 0.1 nm. Combinations of any two of these upper and/or lower thicknesses can provide a range selection, for example between about 0.1 nm to about 500 nm, 0.1 nm to about 200 nm, 0.1 nm to about 100 nm, 0.2 nm to 80 nm, 0.3 nm to 40 nm, 0.4 nm to 20 nm, or 0.5 to 10 nm. In one embodiment, the metal oxide surface layer may have a thickness of about between about 0.1 nm to about 10 nm. The thickness of the metal oxide surface layer may be substantially the same as the thickness of the exfoliated metal oxide nanosheet layer.

The liquid metal film comes into contact with the oxygen atmosphere to from the metal oxide surface layer. The term “contacting” or “contact” as used herein may include allowing two species to react, interact, or physically touch, wherein the two species may be a liquid metal film and oxygen atmosphere, or a metal oxide surface layer and a target substrate configured to adhere to the metal oxide surface layer, as described herein. The metal oxide surface layer may form within seconds following generation of the liquid metal film. If the concentration of oxygen in the oxygen atmosphere is low, the metal oxide surface layer may take longer to form following generation of the liquid metal film.

In some embodiments, the liquid metal film is contacted with the oxygen atmosphere for a period of time of at least about 1, 2, 5, 10, 15, 20, 30, 40, 50, 60, 90, 120, or 180 seconds to form the metal oxide surface layer. In some embodiments, the liquid metal film is contacted with the oxygen atmosphere for a period of time of less than about 180, 120, 90, 60, 50, 40, 30, 20, 15, 10, 5, 2 or 1 seconds to form the metal oxide surface layer. Combinations of any two of these upper and/or lower times can provide a range selection, for example between about 1 second to about 120 seconds, about 1 seconds to about 60 seconds, about 1 second to about 10 seconds, about 1 seconds to about 5 seconds, about 2 seconds to about 120 seconds, about 3 seconds to about 120 seconds, about 3 seconds to about 10 seconds, or about 3 seconds to about 5 seconds. It will be appreciated that the longer the contact time with the oxygen atmosphere, thicker metal oxide surface layers may be provided. In some embodiments or examples, the inventors have identified that a contact time of between about 3 seconds to about 10 seconds may provide further advantages, including an ultra-thin metal oxide surface film. Such short contact time can limit the exposure to oxygen thereby controlling the thickness of the metal oxide surface layer, and also in some embodiments control the metal oxide phase that is generated.

In some embodiments, there may be advantages in initially exposing the liquid metal film with the oxygen atmosphere for longer period of times prior to a “pre-conditioning step” (defined below) which forms a thick oxide layer which is removed (i.e. cleaned from the surface) to regenerate a fresh oxide layer of controlled thickness for exfoliation. For example, where an initial pre-conditioning step is required, the oxygen atmosphere may be maintained for a period of time of at least about 1, 5, 10, 20, 30, 60 seconds (1 min), 2, 5, 10, 15, 20, 30 or 60 min. Combinations of any two of these times can provide a range selection, for example between about 1 min to about 60 min.

In one embodiment, the metal is heated in the oxygen environment and the metal oxide surface layer is generated in-situ on the liquid metal film. For example, the metal oxide surface layer may form while the liquid metal film is being generated, where, once the metal has melted to generate the liquid metal film, the metal oxide surface layer has already formed or begun to form. It will be appreciated that in this embodiment, the metal oxide surface layer forms in-situ on the surface of the liquid metal film.

According to some embodiments or examples, it was also identified that before the start of the process and/or after several exfoliations of a metal oxide surface layer from a single liquid metal film, the surface of the film (e.g. droplet) may feature thicker surface oxides due to initially present oxide layers on the metal/liquid metal film and/or due to mechanical agitation after several preceding exfoliations. To mitigate variability in nanosheet thickness which may result from exfoliating these thicker surface oxides, the surface of the liquid metal film may be cleaned periodically (i.e. a “pre-conditioning” step) prior to exfoliation. In some embodiments, after step b) and prior to step c), the metal oxide surface layer is removed from the liquid metal film to expose fresh liquid metal film to the oxygen atmosphere to form a regenerated metal oxide surface layer. The regenerated metal oxide surface layer is then exfoliated to form the metal oxide nanosheet. The metal oxide surface layer may be removed by sweeping a cleaning substrate over the surface of the liquid metal film to remove the oxide layer. In some embodiments, the metal oxide surface layer is removed by contacting the metal oxide surface layer with a heated glass substrate. The heated glass substrate may be a heated glass slide or glass rod (i.e. a Pasteur pipette). The inventors have identified that by periodically cleaning the surface of the liquid metal film, a single liquid metal film can be used to prepare numerous metal oxide nanosheets having uniform thicknesses.

### Target Substrate and Exfoliation of the Metal Oxide Surface Layer to Form the Metal Oxide Nanosheet Layer

The metal oxide surface layer forms the metal oxide nanosheet layer. For example, once the liquid metal film comprising a metal oxide surface layer has been generated, the metal oxide surface layer is exfoliated from the liquid metal film to form the metal oxide nanosheet layer. It will be appreciated that unlike chemical vapour deposition, the metal oxide surface layer is grown on the surface of the liquid metal film and not on the target substrate, and after exfoliation the metal oxide surface layer becomes the metal oxide nanosheet layer. This exfoliation is achieved by contacting the metal oxide surface layer with a target substrate. In some embodiments, the process comprises contacting the metal oxide surface layer with a target substrate, and exfoliating the metal oxide surface layer from the supporting substrate to form a metal oxide nanosheet layer on the target substrate.

The target substrate is configured to adhere to the metal oxide surface layer. The target substrate may be configured to form a covalent interaction between the surface of the target substrate and the metal oxide surface layer. Alternatively, the target substrate may form a weaker electrostatic interaction (e.g. hydrogen bond) or van der Waals interaction (e.g. dipole-dipole, dipole-induced dipole, London dispersion) between the surface of the target substrate and the metal oxide surface layer.

In one embodiment, the target substrate has a surface comprising terminating oxygen atoms (i.e. is oxygen terminated) for adhering the metal oxide surface layer to the surface of the target substrate. The presence of terminating oxygen atoms on the target substrate renders the target substrate polar. The metal oxide surface layer have more affinity towards polar substrates (i.e. oxygen terminated target substrate) rather than towards the liquid metal film. By contacting the metal oxide surface layer with the surface of the target substrate comprising terminating oxygen atoms, a covalent interaction can form between the metal oxide surface layer and the terminating oxygen atoms. Following contact with the target substrate, the metal oxide surface layer can be removed from the metal liquid film on the supporting substrate via exfoliation (e.g. by peeling off the target substrate with the metal oxide surface layer adhered to the substrate surface). Once exfoliation is complete, the metal oxide surface layer forms the metal oxide nanosheet.

As described above, in some embodiments or examples, the process may not require a separate forced cooling step to form the metal oxide nanosheet from the exfoliated metal oxide surface layer. In contrast, a forced external cooling may provide various drawbacks, including surface cracking, polycrystallinity and/or variable thicknesses, which may be detrimental to some applications. In some embodiments, once exfoliated onto the target substrate, the metal oxide nanosheet layer or layers is naturally cooled to ambient temperature. It will be understood that this is not a forced cooling step.

It will be appreciated that the metal oxide nanosheet remains adhered to the target substrate, although in some embodiments it can be delaminated from the target substrate to provide a discrete metal oxide nanosheet.

In one embodiment, the target substrate may comprise an inorganic oxide or an organic polymeric substrate. The target substrate may be configured to withstand high temperatures, for example the heating temperature selected to melt the metal to form the liquid metal film. In one embodiment, the target substrate is a material that can withstand temperatures of at least 400° C. or more. Any inorganic oxide or organic polymeric substrates known to the skilled person may be used as the target substrate. In some embodiments, the target substrate may comprise an inorganic oxide selected from the group consisting of alumina (e.g. sapphire), silica, ceria, zirconia, and titania. In some embodiments, the organic polymeric substrate may be selected from polyimide, polyethylene napthalate or polyethylene terephthalate. Other suitable inorganic oxides may also be used.

In one embodiment, the target substrate comprises silicon dioxide (SiO₂). The silicon dioxide may form the outer layer of the target substrate, for example as an oxide coating on silicon (Si) or quartz. In one embodiment, the target substrate comprises a surface comprising terminating oxygen atoms provided by a layer of SiO₂. The target substrate may comprise crystalline SiO₂. The target substrate may comprise α-SiO₂. The inventors have surprisingly identified that the interaction between the atomic layers of the metal oxide layer (e.g. Zn—O layers) and the SiO₂ target substrate can induce a buckling in the metal oxide layer, particularly at the interface between the metal oxide layer and the SiO₂ target substrate. This buckling creates an electric dipole within the metal oxide nanosheet, and in some embodiments results in a significantly large piezoelectric coupling coefficient.

The target substrate may be flexible, e.g. a wafer. The target substrate may have a thickness. For example, the target substrate may be a thin flexible material, such as a SiO₂ wafer. Advantages may be provided by a flexible target substrate including finer control of the contact and exfoliation at step c), by allowing for a “roll” on and off motion to provide both contact and exfoliation in one motion.

The surface of the target substrate that contacts the metal oxide surface layer may have any suitable shape, including for example disc, square, rectangular, and ellipsoid etc. The target substrate may be any suitable dimension to provide a surface to contact with the metal oxide surface layer. For example, the target substrate may have a diameter (if disc shape) or a length and width (if square or rectangular) that is greater than the diameter of the liquid metal film.

The force at which the target substrate makes contact with the metal oxide surface layer and liquid metal film (e.g. droplet) may be controlled. When contact is made with excessive force, liquid metal may delaminate from the liquid metal film along with the metal oxide surface layer and attach to the target substrate. Once exposed, the delaminated liquid metal film oxidizes in the oxygen atmosphere, and may create a metal oxide nanosheet with variable thickness. By contacting the target substrate gently (e.g. touch print) with the metal oxide surface layer, delamination of interior liquid metal is minimized.

In some embodiments, prior to contacting with the metal oxide surface layer, the target substrate is heated to a temperature effective to enhance adhesion to the metal oxide surface layer. In some embodiments, the target substrate is heated to a temperature of at least about 200, 250, 300, 350, 400, 450, 500, 550, 600, 650, or 700° C. In some embodiments, the target substrate is heated to a temperature of less than about 700, 650, 600, 550, 500, 450, 400, 350, 300, 250, or 200° C. In some embodiments, the target substrate is heated to a temperature of at least about 300, 320, 340, 360, 380, 400, 420, 440, 460, 480, 500, 520, 540, 560, 580 or 600° C. In some embodiments, the target substrate is heated to a temperature of less than about 600, 580, 560, 540, 520, 500, 480, 460, 420, 400, 380, 360, 340, 320, or 300° C. Combinations of any two of these upper and/or lower temperatures can provide a range selection, for example between about 200° C. to about 700° C., between about 300° C. to about 600° C.

In some embodiments, the target substrate and supporting substrate are heated to substantially the same temperature. In one embodiment, the liquid metal film comprising the metal oxide surface layer is not cooled prior to contacting the metal oxide surface layer with the target substrate (e.g. is maintained at temperature at or above the metal melting temperature as described herein for step a)). According to some embodiments or examples described herein, by pre-heating the target substrate prior to exfoliation, the surface of the metal oxide surface layer can easily adhere to the target substrate and be removed from the liquid metal film, and the thermal shock and/or freezing of the metal oxide surface layer and/or liquid metal film can be minimized. Additionally, if the target substrate is force cooled or cold prior to or during exfoliation, the metal oxide nanosheet layer may form one or more cracks or crystallise rapidly forming polycrystalline domains during exfoliation. Depending on the application, the presence of cracks in the metal oxide nanosheet may not be desirable.

The target substrate may be contacted with the metal oxide surface layer at a suitable angle to maximize transfer of the metal oxide surface layer from the supporting substrate onto the target substrate. In some embodiments, the target substrate may be contacted with the metal oxide surface layer at an angle of contact of at least about 0, 10, 15, 20, 25, 30, 35, 40, 45, 50, 55, 60, 65 or 70° with reference to supporting substrate. In some embodiments, the target substrate may be contacted with the metal oxide surface layer at an angle of contact of less than about 70, 65, 60, 55, 50, 45, 40, 35, 30, 25, 20, 15, 10 or 0° with reference to supporting substrate. Combinations of any two of these upper and/or lower contact angles can provide a range selection, for example between about 20° to about 70° with reference to supporting substrate. In one embodiment, the target substrate may be contacted with the metal oxide surface layer at a contact angle of about 45° with reference to supporting substrate, which may provide further advantages including preparing large area, homogenous metal oxide nanosheets with minimal cracking.

In some embodiments, at least 10, 20, 30, 40, 50, 60, 70, 80, 90 or 100% of the surface area of the target substrate is contacted with the metal oxide surface layer. In some embodiments, less than 90, 80, 70, 60, 50, 40, 30, 20 or 10% of the surface area of the target substrate is contacted with the metal oxide surface layer. Combinations of any two of these upper and/or lower % surface areas can provide a range selection, for example between about 50% to about 100% of the target substrate is contacted with the metal oxide surface layer.

The target substrate may be contacted with the metal oxide surface layer for a suitable period of time to adhere the oxide surface layer to the surface of the target substrate prior to exfoliating the metal oxide surface layer from the supporting substrate. In some embodiments, the metal oxide surface layer is contacted with a target substrate for a period of time of at least about 0.1, 0.2, 0.5, 0.8, 1, 2, 5, 10, 15, 20, 25, 30, 40, 50 or 60 seconds prior to exfoliating the metal oxide surface layer from the supporting substrate. In some embodiments, the metal oxide surface layer is contacted with the target substrate for a period of time of less than about 60, 50, 40, 30, 25, 20, 15, 10, 5, 2, 1, 0.8, 0.5, 0.2 or 0.1 seconds prior to exfoliating the metal oxide surface layer from the supporting substrate. Combinations of any two of these upper and/or lower contact times can provide a range selection, for example between about 0.1 seconds to about 60 seconds prior to exfoliating the metal oxide surface layer from the supporting substrate. By extending the contact time, thicker metal oxide nanosheets can be obtained.

To exfoliate the metal oxide surface layer from the supporting substrate, the target substrate and the adhered metal oxide surface layer may be lifted away from the supporting substrate by any suitable means. For example, the target substrate may be contacted with the metal oxide surface layer by a “roll” on and off motion which provides both contact and exfoliation in one motion (e.g. the target substrate is in contact with the metal oxide surface layer at one point, yet exfoliating the metal oxide surface layer from the supporting substrate at another point, during the single “roll” on and off motion). Other contact and exfoliation applications are also possible, for example pressing the target substrate down onto the metal oxide surface layer to form contact, and then subsequently lifting the target substrate off the supporting substrate to exfoliate the metal oxide surface layer.

The target substrate may be contacted with the metal oxide surface layer for a suitable period of time to adhere the oxide surface layer to the surface of the target substrate prior to exfoliating the metal oxide surface layer from the supporting substrate. In some embodiments, the metal oxide surface layer is contacted with a target substrate for a period of time of at least about 0.1, 0.2, 0.5, 0.8, 1, 2, 5, 10, 15, 20, 25, 30, 40, 50 or 60 seconds prior to exfoliating the metal oxide surface layer from the supporting substrate. In some embodiments, the metal oxide surface layer is contacted with the target substrate for a period of time of less than about 60, 50, 40, 30, 25, 20, 15, 10, 5, 2, 1, 0.8, 0.5, 0.2 or 0.1 seconds prior to exfoliating the metal oxide surface layer from the supporting substrate. Combinations of any two of these upper and/or lower contact times can provide a range selection, for example between about 0.1 seconds to about 60 seconds prior to exfoliating the metal oxide surface layer from the supporting substrate. By extending the contact time, thicker metal oxide nanosheets can be obtained.

Depending on the size of the metal liquid film, exfoliating the metal oxide surface layer from the supporting substrate exposes fresh liquid metal film to the oxygen atmosphere to form a regenerated metal oxide surface layer. Accordingly, in one embodiment, the process comprises contacting the metal oxide surface layer with a target substrate, and exfoliating the metal oxide surface layer from the liquid film (e.g. from the liquid metal melt-air interface) to form a metal oxide nanosheet layer on the target substrate. The regenerated metal oxide surface layer forms when liquid metal film that was previously covered by the metal oxide surface layer is exposed to the oxygen atmosphere following exfoliation, and subsequently oxidized to regenerate the metal oxide surface layer.

Varying thicknesses of metal oxide nanosheets can be obtained by multiple consecutive exfoliations. In some embodiments, the process further comprises a step of contacting the regenerated metal oxide surface layer with the metal oxide nanosheet layer (which is on the surface of the target substrate), and exfoliating the regenerated metal oxide surface layer from the supporting substrate to form a multilayered metal oxide nanosheet on the target substrate. In this way, metal oxide nanosheets of varying thicknesses can be prepared. In some embodiments, a single liquid metal film (e.g. liquid metal droplet) may be used to prepare multiple metal oxide nanosheets.

Multilayered metal oxide nanosheets comprising different metal oxide nanosheet layers can be formed using the process described herein. For example, a first liquid metal film comprising a first metal (e.g. Zinc) may be prepared according to the process described herein to form a form a first metal oxide surface layer (e.g. ZnO) which is exfoliated onto the target substrate to form a metal oxide nanosheet layer. A second liquid metal film comprising a second metal (e.g. iron) may be prepared according to the process described herein to form a second metal oxide surface layer (e.g. Fe₃O₄). The second metal oxide surface layer is then contacted with the first metal oxide nanosheet layer, and exfoliated to form a multilayered metal oxide nanosheet comprising different metal oxide nanosheet layers. In some embodiments, the multilayered metal oxide nanosheet may comprise alternating metal oxide nanosheet layers of different composition.

It will be appreciated that following exfoliation of the metal oxide surface layer from the supporting substrate, the metal oxide surface layer is adhered to the target substrate. The metal oxide surface layer forms the metal oxide nanosheet layer.

It will also be appreciated that the liquid metal-based synthesis approach described herein is very different to other processes used to prepare metal oxide nanosheets, such as chemical vapour deposition. For chemical vapour deposition, a metal precursor/powder is evaporated under vacuum at high temperatures to generate a gas phase comprising the metal species. The metal gas phase then subsequently reacts with oxygen to form a metal oxide at the surface of a heated substrate, which subsequently grows into the metal oxide film. Importantly, the metal precursor/powder is consumed upon evaporation into a gaseous phase, and the subsequent metal oxide layer is grown separately on the desired substrate. In contrast, the metal oxide surface layer of the present liquid metal-based synthesis approach is generated (i.e., grown) on the surface of the liquid metal film following contact with oxygen which converts the liquid surface to the metal oxide surface layer. The as-grown metal oxide surface layer is then exfoliated onto the target substrate to form the metal oxide nanosheet. Unlike chemical vapour deposition, no additional growth step is required as the metal oxide layer has already formed on the surface of the liquid metal film and can be simply exfoliated and transferred onto the surface of the target substrate thus forming the metal oxide nanosheet layer. In one embodiment, the heating of the metal is performed at ambient pressure (i.e., not under a vacuum), which may enable the use of a variety of target substrates.

It will also be appreciated that the liquid-metal based synthesis approach described herein is performed under conditions effective to melt the metal to generate the liquid metal film with little to no evaporation of the metal occurring. For example, the liquid metal-based synthesis approach described herein only requires short heating times (e.g., within seconds to minutes) effective to melt the metal to generate the liquid metal film, as opposed to chemical vapour deposition processes which often require hour long reaction times at high reaction temperatures to facilitate complete evaporation of the metal precursor/powder into a metal gas phase. One advantage of the present liquid metal-based synthesis approach according to at least some embodiments or examples described herein is that metal oxide nanosheets can be prepared over relatively short timeframes, thus requiring less thermal energy and subsequent operational cost compared to other methods such as chemical vapour deposition.

### Metal Oxide Nanosheets

The present disclosure provides a process for preparing metal oxide nanosheets. The term “nanosheet” refers a substantially two-dimensional (2D) structure with thickness in a scale ranging from 0.1 to 100 nm. The width and length dimensions (i.e. the lateral size/area) of the nanosheet may be greater than the thickness dimensions. The metal oxide nanosheet may comprise one or more metal oxide nanosheet layers. The metal oxide nanosheet may have a certain thickness along the c-axis across the nanosheet, often referred to as an axial thickness across the metal oxide nanosheet.

The metal oxide nanosheet may have a lateral length and/or width of at least of at least 0.1, 0.2, 0.3, 0.4, 0.5, 0.6, 0.7, 0.8, 0.9, 1, 1.1, 1.2, 1.3, 1.4, 1.5, 1.6, 1.7, 1.8, 2, 2.5, 3, 4, 5, 6, 7, 8, 9 or 10 cm. In some embodiments, the metal oxide nanosheet may have a lateral length and/or width of less than 10, 9, 8, 7, 6, 5, 4, 3, 2.5, 2, 1.8, 1.7, 1.6, 1.5, 1.4, 1.3, 1.2, 1.1, 1, 0.9, 0.8, 0.7, 0.6, 0.5, 0.4, 0.3, 0.2 or 0.1 cm. Combinations of any two of these upper and/or lower lateral length and/or width dimensions can provide a range selection, for example between about 0.1 cm to about 10 cm, between about 0.2 cm to about 5 cm, or between about 0.5 cm to about 2 cm. In one embodiment, the metal oxide nanosheet may have a lateral length and/or width has an average of about 1 cm. The metal oxide nanosheet may have a lateral area of at least 0.01, 0.05, 0.1, 0.5, 1, 5, 10, 15, 20, 25, 30, 35, 40, 45, 50, 60, 70, 80, 90 or 100 cm². The metal oxide nanosheet may have a lateral area of less than 100, 90, 80, 70, 60, 50, 45, 40, 35, 30, 25, 20, 15, 10, 5, 1, 0.5, 0.1, 0.05, or 0.01 cm². Combinations of any two of these upper and/or lower lateral area dimensions can provide a range selection, for example between about 0.01 cm² to about 100 cm².

The process described herein can prepare metal oxide nanosheets with controlled thicknesses, including sub-nanometre thick nanosheets. In some embodiments, the metal oxide nanosheet may have an axial thickness along the c-axis of at least 0.1, 0.2, 0.3, 0.4, 0.5, 0.6, 0.7, 0.8, 0.9, 1, 2, 3, 4, 5, 6, 7, 8, 9, 10, 12, 14, 16, 18, 20, 40, 80, 100, 200 or 500 nm. In some embodiments, the metal oxide nanosheet may have an axial thickness along the c-axis of less than 500, 200, 100, 80, 40, 20, 18, 16, 14, 12, 10, 9, 8, 7, 6, 5, 4, 3, 2, 1, 0.9, 0.8, 0.7, 0.6, 0.5, 0.4, 0.3, 0.2 or 0.1 nm. Combinations of any two of these upper and/or lower thicknesses can provide a range selection, for example between about 0.1 nm to about 100 nm, 0.2 nm to 80 nm, 0.3 nm to 40 nm, 0.4 nm to 20 nm, or 0.5 to 10 nm. In one embodiment, the metal oxide nanosheet may have an axial thickness along the c-axis of about between about 0.1 nm to about 10 nm. In some embodiments, the metal oxide nanosheet may be between about 1 to about 10 unit cells thick, for example about 2, 3, 4, 5, 6, 7, 8, 9, or 10 unit cells thick. In one embodiment, the thickness of the metal oxide nanosheet may be substantially the same thickness as the metal oxide surface layer. The thickness of the metal oxide nanosheet may be measured using scanning electron microscopy or atomic force microscopy (AFM).

The process described herein can prepare metal oxide nanosheet comprises one or more metal oxide nanosheet layers. The metal oxide nanosheet layers may be the same or different. For example, each metal oxide nanosheet layer may be a zinc oxide nanosheet layer which combined form a zinc oxide nanosheet of a specific thickness. It will be appreciated that the more metal oxide nanosheet layers that are present, the thicker the metal oxide nanosheet.

In some embodiments, the metal oxide nanosheet may comprise at least about 1, 2, 3, 4, 5, 6, 7, 8, 9, 10, 12, 15, 20, 25, 30, 40, 50, 60, 70, 80, 90 or 100 metal oxide nanosheet layers. In some embodiment, the metal oxide nanosheet may comprise less than 100, 90, 80, 70, 60, 50, 45, 40, 35, 30, 25, 20, 15, 10, 9, 8, 7, 6, 5, 4, 3, or 2 metal oxide nanosheet layers. Combinations of any two of these upper and/or layer numbers can provide a range selection, for example between about 1 to about 100 metal oxide nanosheet layers. The number of metal oxide nanosheet layers can be varied by controlling the synthesis conditions (e.g. oxygen atmosphere, contact time with target substrate etc.) or by repeating step c) of the process multiple times.

The metal oxide nanosheet layer or layers may be delaminating from the target substrate to obtain discreet metal oxide nanosheets. Any suitable delamination process can be used. Alternatively, the metal oxide nanosheets may remain adhered to the target substrate. In some embodiments, the metal oxide nanosheet layer or layers may be delaminated from the target substrate onto any suitable substrate.

Zinc oxide (ZnO) nanosheets

The present disclosure provides a process for preparing zinc oxide (ZnO) nanosheets. In some embodiments, the metal is zinc metal, the liquid metal film is a liquid zinc film, the metal oxide surface layer is a zinc oxide surface layer, the metal oxide nanosheet is a zinc oxide nanosheet. The present inventors have prepared large sheets of 2D zinc oxide with controlled nanometer thicknesses.

The process for preparing the zinc oxide nanosheets may comprise:
a) heating zinc metal that is provided on a supporting substrate to a temperature effective to melt the zinc metal to generate a liquid zinc metal film on the supporting substrate,
b) contacting the liquid zinc metal film with an oxygen environment to generate a zinc oxide surface layer on the liquid zinc metal, and
c) contacting the zinc oxide surface layer with a target substrate, and exfoliating the zinc oxide surface layer from the supporting substrate to form a zinc oxide nanosheet layer on the target substrate.

The process parameters described herein under the heading “Process for preparing metal oxide nanosheets” including for example the heating temperature, supporting substrate, target substrate, oxygen atmosphere, liquid metal film (e.g. droplet) dimensions, contact times and exfoliation etc. may also be used to prepare the zinc oxide nanosheets are described herein.

In some embodiments, the zinc oxide nanosheet may have a lateral length and/or width of at least of at least 0.1, 0.2, 0.3, 0.4, 0.5, 0.6, 0.7, 0.8, 0.9, 1, 1.1, 1.2, 1.3, 1.4, 1.5, 1.6, 1.7, 1.8, 2, 2.5, 3, 4, 5, 6, 7, 8, 9 or 10 cm. In some embodiments, the zinc oxide nanosheet may have a lateral length and/or width of less than 10, 9, 8, 7, 6, 5, 4, 3, 2.5, 2, 1.8, 1.7, 1.6, 1.5, 1.4, 1.3, 1.2, 1.1, 1, 0.9, 0.8, 0.7, 0.6, 0.5, 0.4, 0.3, 0.2 or 0.1 cm. Combinations of any two of these upper and/or lower lateral length and/or width dimensions can provide a range selection, for example between about 0.1 cm to about 10 cm, between about 0.2 cm to about 5 cm, or between about 0.5 cm to about 2 cm. In one embodiment, the zinc oxide nanosheet may have a lateral length and/or width has an average of about 1 cm. The zinc oxide nanosheet may have a lateral area of at least 0.01, 0.05, 0.1, 0.5, 1, 5, 10, 15, 20, 25, 30, 35, 40, 45, 50, 60, 70, 80, 90 or 100 cm². The zinc oxide nanosheet may have a lateral area of less than 100, 90, 80, 70, 60, 50, 45, 40, 35, 30, 25, 20, 15, 10, 5, 1, 0.5, 0.1, 0.05, or 0.01 cm². Combinations of any two of these upper and/or lower lateral area dimensions can provide a range selection, for example between about 0.01 cm² to about 100 cm².

The process described herein can prepare zinc oxide nanosheets with controlled thicknesses, including sub-nanometre thick nanosheets. In some embodiments, the zinc oxide nanosheet may have an axial thickness along the c-axis of at least 0.1, 0.2, 0.3, 0.4, 0.5, 0.6, 0.7, 0.8, 0.9, 1, 2, 3, 4, 5, 6, 7, 8, 9, 10, 12, 14, 16, 18, 20, 40, 80, 100, 200 or 500 nm. In some embodiments, the zinc oxide nanosheet may have an axial thickness along the c-axis of less than 500, 200, 100, 80, 40, 20, 18, 16, 14, 12, 10, 9, 8, 7, 6, 5, 4, 3, 2, 1, 0.9, 0.8, 0.7, 0.6, 0.5, 0.4, 0.3, 0.2 or 0.1 nm. Combinations of any two of these upper and/or lower thicknesses can provide a range selection, for example between about 0.1 nm to about 100 nm, 0.2 nm to 80 nm, 0.3 nm to 40 nm, 0.4 nm to nm, or 0.5 to 10 nm. In one embodiment, the zinc oxide nanosheet may have an axial thickness along the c-axis of about between about 0.1 nm to about 10 nm. In some embodiments, the zinc oxide nanosheet may be between about 1 to about 10 unit cells thick, for example about 2, 3, 4, 5, 6, 7, 8, 9, or 10 unit cells thick.

In some embodiments, the zinc oxide nanosheet may comprise at least about 1, 2, 3, 4, 5, 6, 7, 8, 9, 10, 12, 15, 20, 25, 30, 40, 50, 60, 70, 80, 90 or 100 Zn—O layers. In some embodiment, the zinc oxide nanosheet may comprise less than 100, 90, 80, 70, 60, 50, 45, 40, 35, 30, 25, 20, 15, 10, 9, 8, 7, 6, 5, 4, 3, or 2 Zn—O layers. Combinations of any two of these upper and/or layer numbers can provide a range selection, for example between about 1 to about 100 Zn—O layers. The number of Zn—O layers can be varied by controlling the synthesis conditions (e.g. oxygen atmosphere, contact time with target substrate etc.). In some embodiments, the inventors have identified that zinc oxide nanosheets prepared using the process described herein comprising between about three (3) Zn—O layers to about eight (8) Zn—O layers demonstrate exceptionally high d₃₃ piezoelectric coefficient values (see below) and conversely exceptional piezoelectric characteristics compared to nanosheets prepared using conventional prior art methods.

In some embodiments, the zinc oxide nanosheet may be characterised by an X-ray powder diffraction (XRD) pattern comprising one or more principal peaks located at about 34.4, 36.3, and 47.5 degrees 2θ. Any one or more of these peaks can be used to characterize the zinc oxide nanosheet. The zinc oxide nanosheet may be characterised by the XRD pattern provided in FIG. 11b.

The zinc oxide nanosheet prepared using the liquid-metal based process described herein can demonstrate exceptional piezoelectric properties. Piezoelectricity is described as the electric charge that accumulates in certain solid materials in response to applied mechanical stress. The magnitude of a piezoelectric response can be determined by a materials piezoelectric coefficient d₃₃.

In some embodiments, the zinc oxide nanosheet has a piezoelectric coefficient d₃₃ of at least about 20, 30, 40, 50, 60, 70, 80, 90, 100, 120, 130, 140 or 150 pm/V. In some embodiments, the zinc oxide nanosheet has a piezoelectric coefficient d₃₃ of less than about 150, 140, 130, 120, 100, 90, 80, 70, 60, 50, 40, 30, or 20 pm/V. Combinations of any two of these upper and/or lower d₃₃ values can provide a range selection, for example between 20 pm/V to about 120 pm/V.

In one embodiment, the zinc oxide nanosheet has an axial thickness along the c-axis of about between about 0.5 nm to about 5 nm, e.g. 1.1 nm (i.e. 5 Zn—O layers), and a piezoelectric coefficient d₃₃ of between about 10 pm/V to about 100 pm/V.

The inventors have surprisingly identified that the interaction between the atomic layers of the Zn—O layers and the SiO₂ target substrate can induce a buckling in the zinc oxide layers, particularly at the interface between the zinc oxide layer and the SiO₂ target substrate. This buckling creates an electric dipole within the metal oxide nanosheet, and can result in a significantly large piezoelectric coupling coefficient.

### Sensors and Applications

The zinc oxide nanosheets described herein demonstrate high out of plane piezoelectricity. The process may comprise the step of preparing a piezoelectric generator or sensor comprising the metal oxide nanosheet layer prepared by the process described herein. Accordingly, in one aspect there is provided a piezoelectric generator or sensor comprising a metal oxide nanosheet according to any embodiments or examples as described herein, including prepared by the process described herein.

In some embodiments, the metal oxide nanosheets (e.g. zinc oxide nanosheets) may be used to fabricate a piezoelectric generator or sensor. By applying strain or pressure to the piezoelectric generator or sensor, an output voltage is generated which can be detected (i.e. sensing) and in some embodiments provide an external power source (i.e. generator), for example through the conversion of mechanical energy into electricity.

In one embodiment, the piezoelectric generator comprising the metal oxide nanosheets (e.g. zinc oxide nanosheets) is an energy harvesting device, and owing to the improved piezoelectric properties of the metal oxide nano sheets, may be used to harvest energy at large scale.

The piezoelectric generator or sensor may be flexible, that is a flexible device. The piezoelectric generator or sensor may be a wearable device. In general terms, the piezoelectric generator or sensor may comprise at least two electrode layers and a metal oxide nanosheet (e.g. the zinc oxide nanosheet) provided as an intervening layer between the two electrode layers. The electrode layers may be any suitable electrode, for example Cr—Au electrodes.

To prepare the piezoelectric generator or sensor, the zinc oxide nanosheet may be delaminated from the target substrate onto a suitable flexible substrate, for example mica or polydimethylsiloxane (PDMS). The flexible substrate may have a thickness of less than 0.1, 0.5, 1, 1.5, 2, 2.5, 3, 3.5, 4 or 5 mm. Combinations of any two of the values can form a range selection, for example between about 1 mm and about 5 mm. The flexible substrate may be substantially perpendicular to the zinc oxide nanosheet electrodes. For example, the zinc oxide nanosheet may be extending vertically off the surface of the flexible substrate. The electrodes may be deposited onto the surface of the substrate either side of the zinc oxide nanosheet.

In some embodiments, each electrode may independently have a width of at least 500, 450, 400, 350, 300, 250, 200, 150, 100, 70, 50, 20 or 10 p.m. Combinations of any two of the values can form a range selection, for example between about 10 μm to about 500 μm.

In some embodiments, the spacing between each electrode (which defines the space where the intervening layer comprising the zinc oxide nanosheet) may be at least about 10, 20, 30, 40, 50, 70, 80, 100, 150, 200, 300 or 500 μm. Combinations of any two of the values can form a range selection, for example between about 20 μm to about 70 μm. The piezoelectric generator or sensor may comprise multiple electrode layers. The electrodes may be connected by any suitable electrical wire. The piezoelectric generator or sensor may be encapsulated with an encapsulation layer applied to the top of the generator or sensor.

Other sensors comprising the zinc oxide nano sheets prepared herein also include optical sensors, synaptic sensors, and gas sensors.

It will be appreciated that the piezoelectric metal oxide nano sheets described herein find utility across a wide range of industrial applications, and the above examples are not intended to be limiting.

The present application claims priority from Australian Provisional Patent Application No. 2021900097 filed on 18 Jan. 2021, the entire contents of which are incorporated herein by reference.

### EXAMPLES

The present disclosure is further described by the following examples. It is to be understood that the following description is for the purpose of describing particular embodiments only and is not intended to be limiting with respect to the above description.

### Example 1: Mechanism and Theoretical Studies

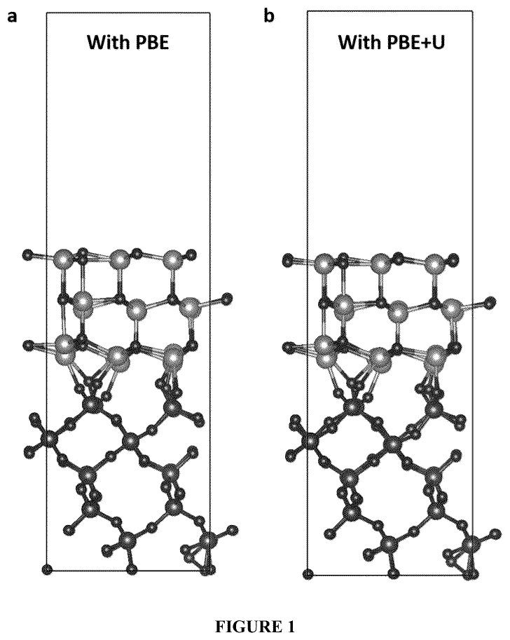

Theoretical calculations were performed using the Vienna Ab inito Simulation Package (VASP), based on DFT. The exchange-correlation functional in the Perdew-Burke-Ernzerhof (PBE) parametrization was used and the ion-electron interaction was described by the projector augmented wave (PAW) method. A plane-wave basis set was used with an energy cut-off of 500 eV. For the ZnO bulk unit cell, the optimized lattice parameters and the atomic structure with the k-point mesh 11×11×5, yielding the lattice parameters a=3.288 Å and c=5.306 Å. The optimized lattice parameters of bulk SiO₂ are a=5.028 Å and c=5.519 Å, using a k-point mesh 5×5×4. For the ZnO monolayers, the optimization of the atomic structure used a k-point mesh 10×10×1. The equilibrium lattice constant for the 3-layer, 5-layer and 8-layer structures was obtained by optimizing the lattice at ten values of the lattice constant, and then fitting the total energies to a third-degree polynomial. The resulting lattice constants were a=3.384 Å for the 3-layer, a=3.394 Å for the 5-layer, and a=3.402 Å for the 8-layer systems. A 3d orbital correction of Zn was carried out using the Hubbard U term, setting U=5 eV, which shows a minimal effect on the structural optimization (as shown in FIG. 1).

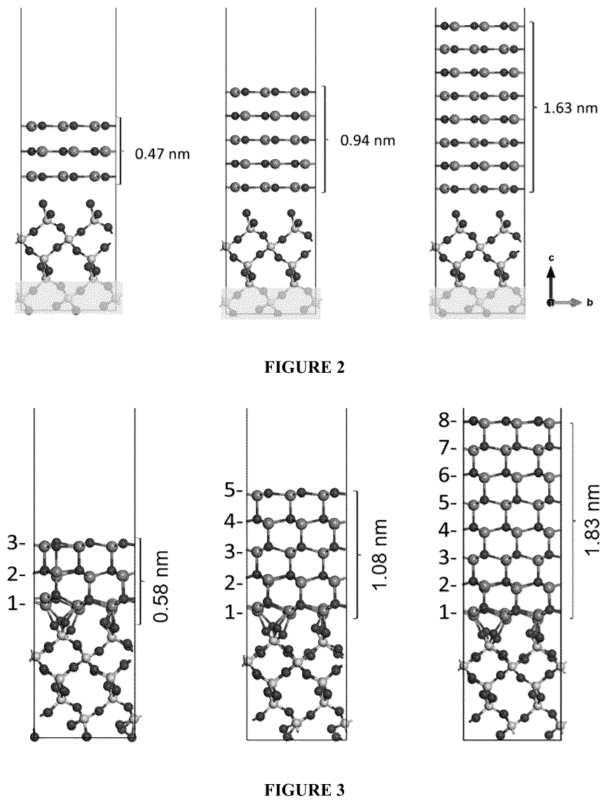

Our initial calculations of the structure of 2D ZnO nanosheets from 3 to up to 8 layers' thick of Zn—O yielded a perfectly flat stacking of the layers (FIG. 2 displays these systems with sp² geometry). However, these flat layers lack the ability to host electric dipoles because the c-axis positions of the two charged species, Zn and O, are effectively equivalent and cancel each other out. By contrast, our experimental observations (presented later) show the possibility of a dipole moment existing along the c-axis of ultra-thin ZnO sheets. This strongly suggests the plausible impact associated with the presence of the substrate. The effect of the substrate on the ZnO nanosheets was examined.

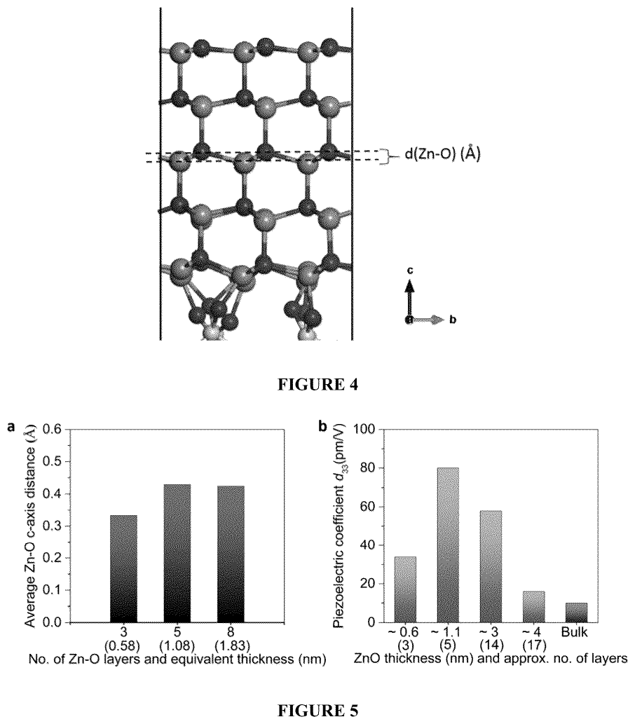

A second set of theoretical calculations considered the effect of the substrate, the ZnO/α-SiO₂ (0001) structure was modelled using 3, 5 and 8 layer-thick of Zn—O nanosheets. FIG. 3 and FIG. 4 displays these systems with wurtzite geometry. The thicknesses of the three Zn—O systems are close to the thicknesses of the experimentally measured samples. A [3×3] ZnO supercell is placed on a [2×2] α-SiO₂ (0001) surface. The two components in this structure, ZnO and α-SiO₂, have a lattice mismatch in the a lattice parameter of approximately 1%, which would not affect the accuracy of the structural optimization. All the atoms are optimized in the system except those covered with grey shaded regions in FIG. 2, and these atoms were fixed by freezing during the calculations to assure bulk behaviour of the α-SiO₂ (including bottom dangling oxygen atoms of α-SiO₂). The result of the structural optimization, (carried out to assess the thermodynamic stability of the system) is shown in FIG. 3. This clearly shows the interaction between the ZnO and α-SiO₂ layers that induces buckling in the ZnO layers and is particularly noticeable in the layers adjacent to the α-SiO₂ layer. This buckling creates an electric dipole within the nanosheet, and hence likely results in a piezoelectric coupling coefficient that is significantly larger than that of bulk ZnO.

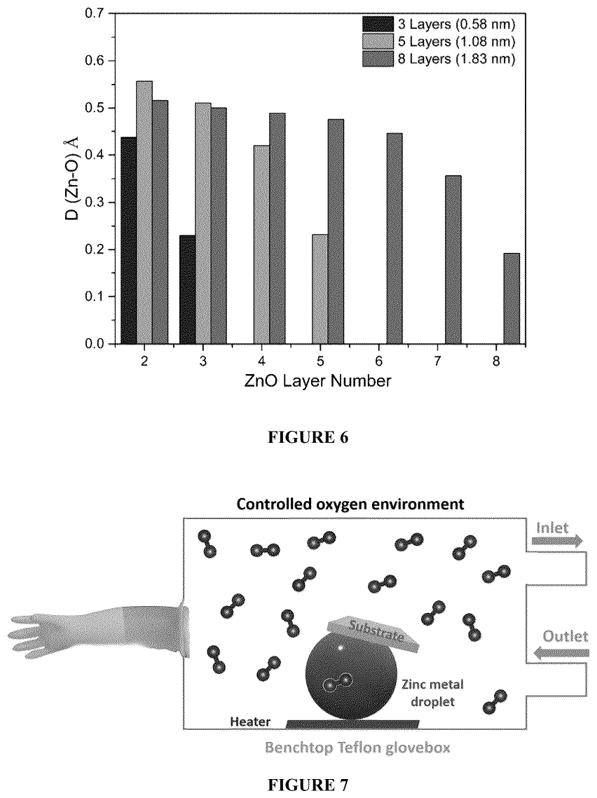

The buckling is quantified in the 3, 5 and 8 layers thick Zn—O systems that is induced by the interaction with α-SiO₂ layer in terms of the average buckling, d_{avg} (Zn—O) as shown in FIG. 3. This is calculated by averaging the c-axis Zn—O distance, d(Zn—O), in each ZnO layer, as depicted by the dotted lines (FIG. 4), and is performed across all layers except layer 1 (FIG. 3). Layer 1 (the layer nearest the substrate) is excluded because it does not contribute to the structure's polarization, due to its direct covalent interaction with the O atoms in the α-SiO₂ surface. FIG. 5a displays the change in d_{avg} (Zn—O) as a function of the number of ZnO layers. The value of d_{avg} (Zn—O) increases as the nanosheet thickness increases from 3 (0.58 nm) to 5 layers (1.08 nm), and then decreases slightly for 8 layers (1.83 nm) (see FIG. 6). The measured d₃₃ is approximately P/σ, where P is the structure's polarization and σ is its stress. Given that P is proportional to d_{avg} (Zn—O), and σ is proportional to the layer thickness in thin films (σ=σₒ[1−ε₁₁+ε₂₂/2εₘ], where ε₁₁, ε₂₂, and εₘ are the strain components), the results in FIG. 5a both re-enforce and support the experimental finding of d₃₃ as presented in FIG. 5b. This suggests that the presence of the α-SiO₂ interface restores buckling to the ZnO nanosheet and reaches a maximum between 5 to 8 Zn—O atomic layers. This corresponds to the thickness where the maximum measured value for d₃₃ is observed (as will be presented later). Thus, the ZnO at a thickness of approximately 1.1 nm (5 Zn—O atomic layers) can theoretically offer the maximum potential piezoactivity. As such, tuning the overall sheet thickness to adjust the contribution of each physical parameter is the key to obtain the maximum d₃₃ values.

### Example 2: Synthesis of Nanosheets

To synthesize millimetre lateral dimensioned ultrathin ZnO sheets, pure zinc metal (99.8%, Roto Metals) was melted on a glass slide heated to 500° C. in a controlled atmosphere (FIG. 7). This temperature was chosen to facilitate melting of the zinc, which typically melts at 420° C., as well to aid the interfacial reaction with the oxygen in the ambient air. A self-limiting Cabrera-Mott reaction occurs forming an oxide layer on the outer exposed surface of the liquid metal droplet. The oxide layer formed at the surface was removed by pre-conditioning using heated glass slides that were exposed to the reflective Zn surface. A heated substrate such as SiO₂/Si was touched lightly to the surface of the droplet to remove the interfacial oxide layer through constructing covalent interactions between the as grown ZnO sheets and the substrate. Varying thicknesses of the synthesized sheets were obtained by multiple consecutive exfoliations from the same area. The as-transferred sheets were used for various characterizations and furthermore studied for their piezoelectric properties.

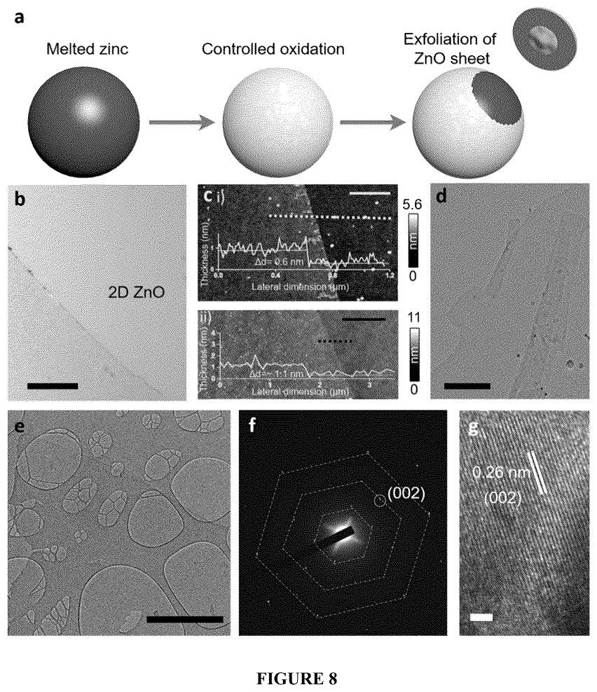

To obtain large area atomically thin ZnO nanosheets, the self-limiting Cabrera-Mott reaction at the Zn metal melt-air interface was used in a controlled environment (FIG. 7), The as-grown ZnO nanosheets were transferred to the desired substrates with the assistance of covalent interaction supported exfoliation, i.e. removed from the Zn liquid melt-air interface that is not polarized as shown in FIG. 8a. Moreover, terminated oxygen atoms at substrate surface and high synthesis temperature i.e. 500° C. helps in forming covalent interaction between as-exfoliated ZnO sheets and substrate. These sheets have more affinity towards polar substrates i.e. oxygen terminated rather than towards the parent liquid metal. The natural affinity of the self-controlled oxidation at the metal-melt surface, and absence of any bonds to the melt, make this process versatile and consistent with synthesizing homogenous, large area atomically thin sheets of ZnO.

### Example 3: Characterisation of Nanosheets

Lateral dimensions and surface morphologies of ZnO nanosheets were assessed using TEM (JEOL-1010, 100 kV). The ZnO nanosheets were delaminated onto Cu-carbon grids (ProScitech, Australia) for observations. HRTEM and SAED were conducted using a JEOL-2100F (200 kV) and images were acquired with a Gatan Orius SC1000 CCD camera. Surface topography was analysed using an AFM (AFM—Bruker Dimension Icon) in Scanasyst mode with a Scanasyst tip with the data processed using Nanoscope Analysis software. Topographic images were obtained using nanosheets exfoliated onto SiO₂/Si wafers.

For the surface composition and valence band analysis, a Thermo Scientific K-alpha XPS spectrometer using a monochromated Al K_{α}(hv=1486 eV) source and a concentric hemispherical electron analyser. A pass energy of 20 or 50 eV was used to measure the survey and core-level spectra of Zn 2p, O 1s, C 1s, respectively. XPS Advantage software was used to perform the peak fitting analysis on these data and the C-C peak at 284.8 eV was used as a surface charge correction reference. Raman spectra were obtained using a Horiba Scientific LabRAM HR evolution at 532 nm laser excitation wavelength and 1800 1/mm grating. Each sample was exposed to the laser at 1% power for 1 s and 600 accumulations. Samples for XPS and Raman spectra measurements were prepared by delaminating the 2D sheets onto 1 cm×1 cm silicon wafers.

XRD patterns and PESA measurements were obtained from samples delaminated onto clean glass slides. The XRD sample was analysed using a Bruker D4 Endeavour Wide Angle X-Ray Diffraction instrument with a wavelength of 1.54060 Å while the PESA measurement was carried out using a Riken Keiki AC-2 photoelectron spectrometer with a UV light source of energy 75 nW while a power law of 0.5 was used to analyze the data. The UV-Vis spectroscopy was performed on a sample delaminated onto a clean quartz slide to obtain the optical absorption spectra on a Perkin Elmer Lambda 1050 Ultraviolet-Visible Spectrophotometer using an integration sphere and with baseline correction.

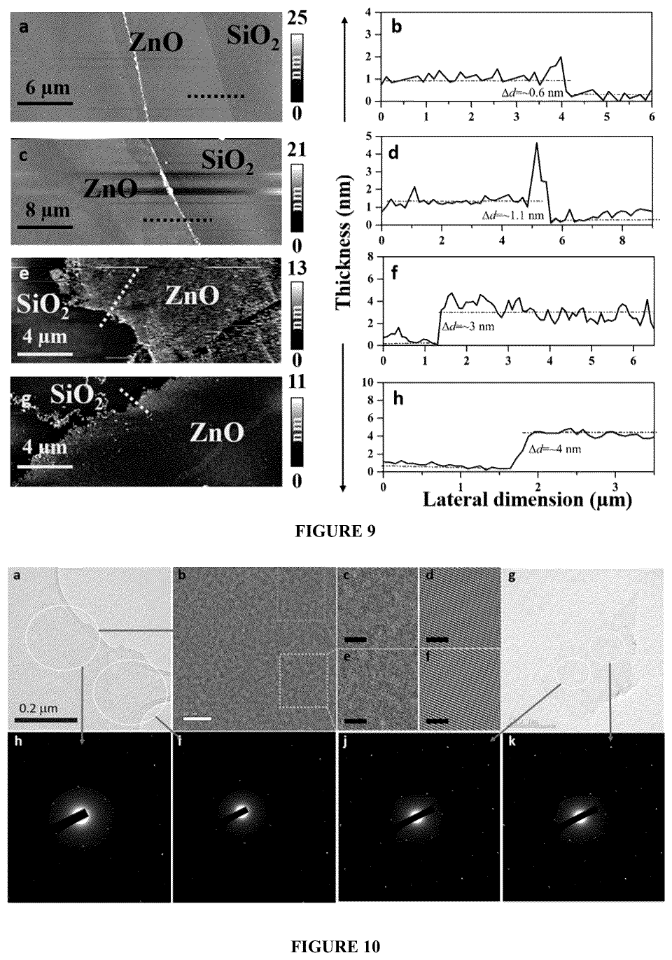

Optical images of the as-synthesized ZnO nano sheets were obtained to confirm the uniformity and continuous nature of the laterally large sheets—which can exceed several square millimetres (FIG. 8b). Atomic force microscopy (AFM) was utilized to confirm the smooth surfaces of the ultrathin sheets transferred to the new substrates. With a single exfoliation step, one and half unit-cell thick (3 Zn—O layers) wurtzite ZnO sheets of 0.6 nm were observed (FIG. 8ci). These can be made thicker simply by extending the exfoliation time to two and half unit-cell thick (5 Zn—O layers), as shown in FIG. 8cii. Moreover, through controlling the synthesis conditions and the exfoliation time, the thickness of the ZnO sheets can easily be controlled, ranging from 0.6 nm to several nanometers. As presented in FIG. 9, it is possible to control the thickness from 0.6 nm to 4 nm to observe its impact on piezoelectric response of 2D ZnO. The ultrathin and transparent nature of the 2D ZnO sheets were further observed in the transmission electron microscope (TEM) images, shown in FIG. 8d, e. Specifically folded edges found in FIG. 8d, highlight the atomically thin features of the ZnO sheets. The ZnO thickness could be controlled to several nanometres simply by modifying the experimental conditions, which are discussed in the Methods Section.

To observe the existence of a hexagonal structure for ultra-thin ZnO, the corresponding selected area electron diffraction (SAED) patterns were recorded, confirming both a high degree of crystallinity and the presence of a hexagonal structure (FIG. 8f). The lattice spacings of 0.26 nm was observed corresponding to the d-spacing value of (002) plane of hexagonal ZnO structure. To observe the crystallinity and growth, high resolution TEM (HRTEM) images were taken again showing the lattice spacing of 0.26 nm corresponding to the (002) plane of ZnO (FIG. 8g). The existence of these (002) planes signified the presence of wurtzite {0001} structure. To confirm the unidirectional growth and monocrystalline nature of the ZnO sheets, HRTEM images and SAED patterns from different areas of two different sheets were recorded as shown in FIG. 10. Both showed the same microstructure at all points, confirming the monocrystalline nature and unidirectional growth of the entire ZnO sheets.

The ZnO sheets were further analysed by Raman spectroscopy, where the expected two peaks of Raman active modes of the as-synthesized ZnO were observed as shown in FIG. 11a. A peak appeared at 440 cm⁻¹ corresponds to the E_{2(high)} mode because of the vibrational characteristics of oxygen atoms in basal planes of ZnO sheets. The 1LO phonon peak appears at 574 cm⁻¹ corresponding to the A1(LO)/E1(LO) mode of ZnO. Such a peak only appears when the c-axis of ZnO is parallel to the sample surface, supporting the HRTEM and SAED findings. A small shift in the peak positions of the as-synthesized thin ZnO sheets (approximately 1.1 nm), in comparison with the previously reported bulk ZnO, might be due to phonon confinement in the ultrathin sheets and/or structural variations (likely due to covalent interactions with the substrate) in the crystal structure.

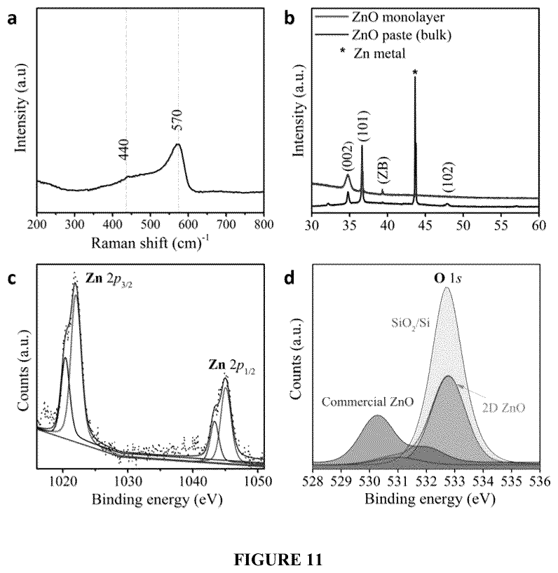

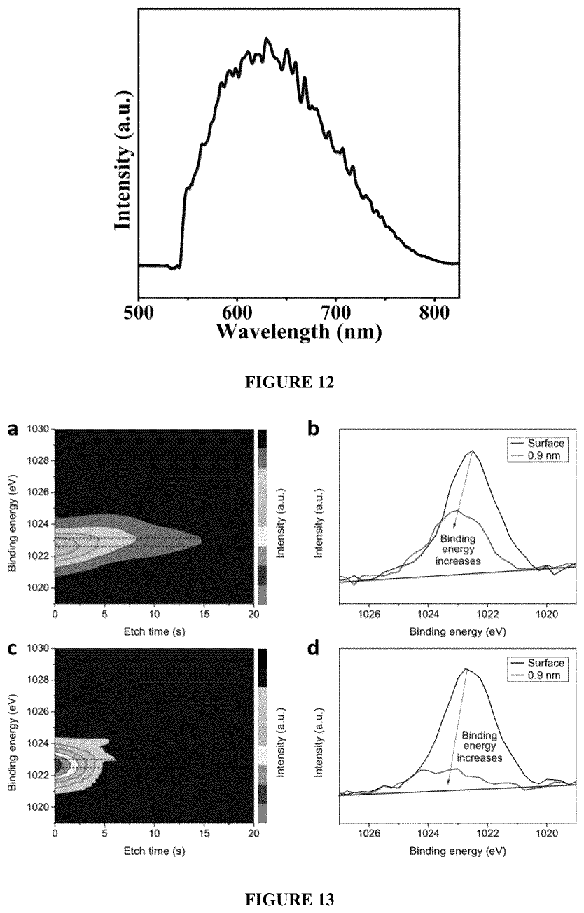

Photoluminescence (PL) measurements show a broad peak in the wavelength 550 to 700 nm as shown in FIG. 12. The presence of such a broad peak within the green wavelength region confirms the structural variation due to coupled oxygen atoms between the α-SiO₂ substrate and ZnO sheets, in addition to the contribution from substrate.

To further examine the crystallinity of the as-synthesized ZnO sheets, X-ray diffraction (XRD) analysis was performed as shown in FIG. 11b (on thicker films of ZnO obtained by multiple contacts). The XRD pattern of ZnO sheets shows 4 major peaks, among these peaks at 34.4°, 36.3°, and 47.5° corresponding to (002), (101) and (102) lattice planes of ZnO according to JCPDS No. 36-1451, indicating that the 2D ZnO constituents are a highly oriented along the c axis, well-matched with wurtzite ZnO lattice parameters a=3.351 Å, b=3.351 Å, c=5.226 Å, P63mc space group. Interestingly, a small peak that appears at 39.1°, typically assigned to a zinc blende (ZB) phase of ZnO according to JCPDS 36-1486, might in fact be due to some structural strain induced by the substrate, which would contribute positively towards the structure dependent properties of the observed piezoactivity.

X-ray photoelectron spectroscopy (XPS) was utilized to determine the nature and bonding states of each surface atom in the atomically thin ZnO sheets. High resolution XPS spectra of Zn 2p and O 1s are shown in FIG. 11c & 11d, respectively. The characteristic doublets at 1021.9 and 1045 eV are found in the Zn 2p region corresponding to the 2p_{3/2} and 2p_{1/2} components, respectively with a separation energy of 23.1 eV, confirming the presence of Zn²⁺ states in the as-grown sheets. As predicted, no metallic Zn peak was detected, confirming the possible wurtzite nature of the as-synthesized sheets. Moreover, the deconvoluted O 1s spectrum can also be resolved into two peaks at 530.9 eV and 532.7 eV assigned to the lattice bound and substrate oxygen, respectively. The slightly higher binding energy for oxygen might be due to deficiency of O²⁻ and a comparison of O 1s from three different samples namely, commercial ZnO, as-synthesized ZnO and α-SiO₂ substrate is shown in FIG. 11d. No significant difference in XPS signatures could be seen between 2-layer to 8-layer ZnO films. Furthermore, to confirm the presence of covalent bonds formed between the ZnO layer and the SiO₂ substrate, XPS depth profile mapping of the Zn 2p_{3/2} peak for ZnO sheets placed on the substrate was recorded, as shown in FIG. 13. With increasing etching depth, a shift towards higher binding energy is observed with a shift of approximately 0.8 eV for the 8-layer and 5-layer ZnO systems. This shift is observed due to the formation of Zn—O—Si bonds. Hence, the XPS confirms formation of covalent Si—O at the boundary between the ZnO sheet and SiO₂ substrate.

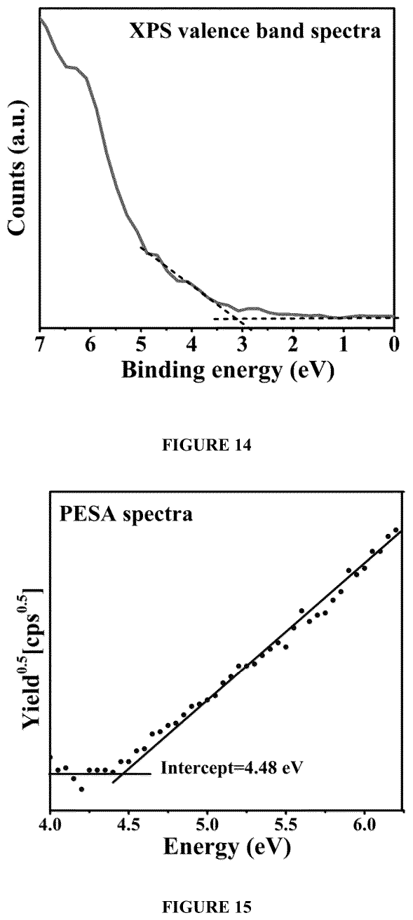

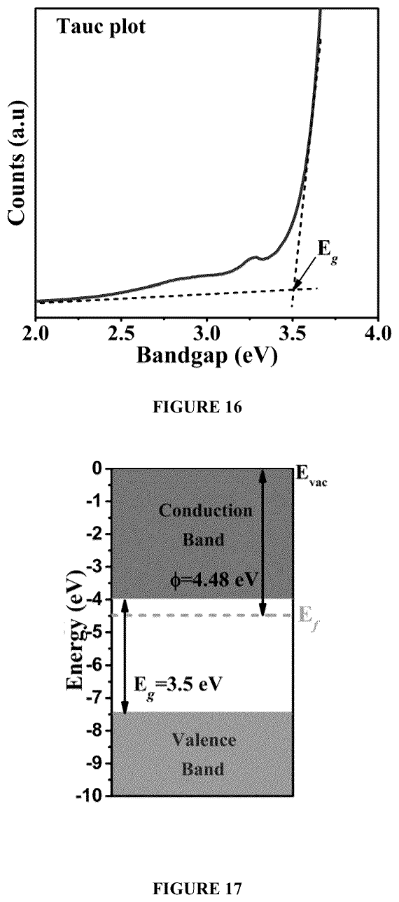

To evaluate the semiconducting properties of the ultrathin ZnO films, the electronic band structure of the nanosheets were determined using Tauc plots from ultraviolet-visible (UV-vis) measurements, together with XPS valence band (VB) spectra and photoelectron spectroscopy in air (PESA) analysis. A VB spectrum is extracted from the XPS analysis for the approximately 1.1 nm ZnO (FIG. 14) indicating how far above the valence band maximum (VBM), the Fermi level lies. While the PESA spectrum indicated the Fermi level is located around 4.48 eV under the vacuum (FIG. 15). The optical band gap value of 3.5 eV was extracted from a Tauc plot based on the UV-Vis spectrum revealing the difference between the VBM and the conduction band minimum (CBM) (FIG. 16). This shows an opening of the bandgap with reference to the typical 3.2 eV bandgap of bulk ZnO. Based on these observations, an electronic structure is constructed to represent the band structure of the extra-large ZnO sheets, of approximately 1.1 nm thickness (FIG. 17) and confirming the n-type nature of the as-synthesized sheets. As such these n-type atomically thin ZnO sheets are stable in atmospheric environment.

### Example 4: Piezoelectric Properties of Nanosheets

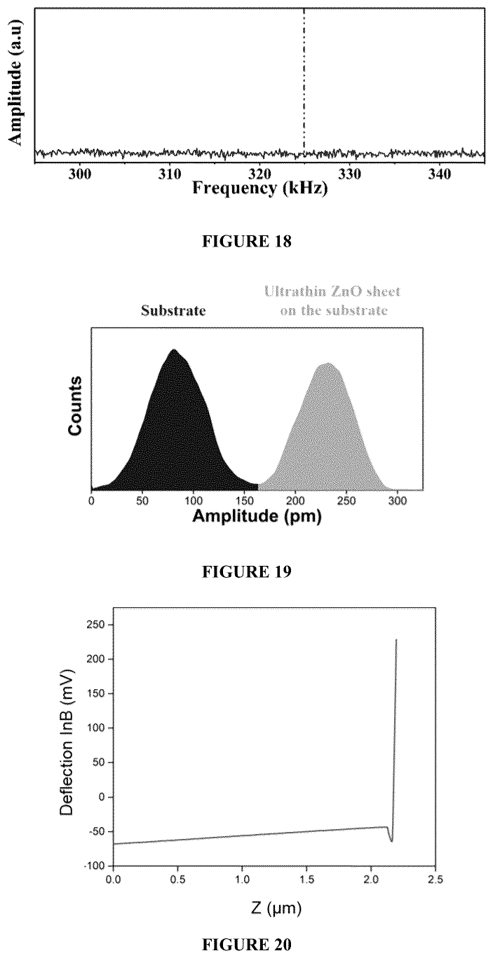

Piezoelectric measurements were performed using the PFM mode (Digital Instruments D3100, Bruker, CA, US). These data were analysed using the Nanoscope Analysis software. The substrate with the delaminated ZnO sheets was attached to a metal chuck with silver paste to earth the substrate and remove any surface charge that may interfere with the measurements. A conductive tip (Bruker, SCM-PIT-V2) of spring constant 3 N/m was used to reduce any contributions due to the effect of electrostatic discharge. The measurements were made in Low Speed mode with varying drive amplitudes and a drive frequency of 325 kHz for the PFM mode (FIG. 18). The statistical analysis of voltage amplitude difference was done as shown in FIG. 19.

The full piezoelectric properties of as-synthesized ZnO sheets of approximately 1.1 nm thickness with the largest out of plane piezoelectric coupling coefficient were determined. The preservation of the hexagonal structure in the ZnO sheets, regardless of a reduction in thickness, justifies the generation of an out-of-plane piezoelectricity along the c-axis due to the lack of centro symmetric structure. As such, structurally, the Zn cations (Zn²⁺) and O anions (O²⁻) are coordinated in such a way that their centres overlap. Following the application of an external compressive force in the vertical direction, the crystal should generate charged inner dipoles (polarization effect) as these centres are displaced, resulting in larger displacement and consequently yields a high piezoresponse.

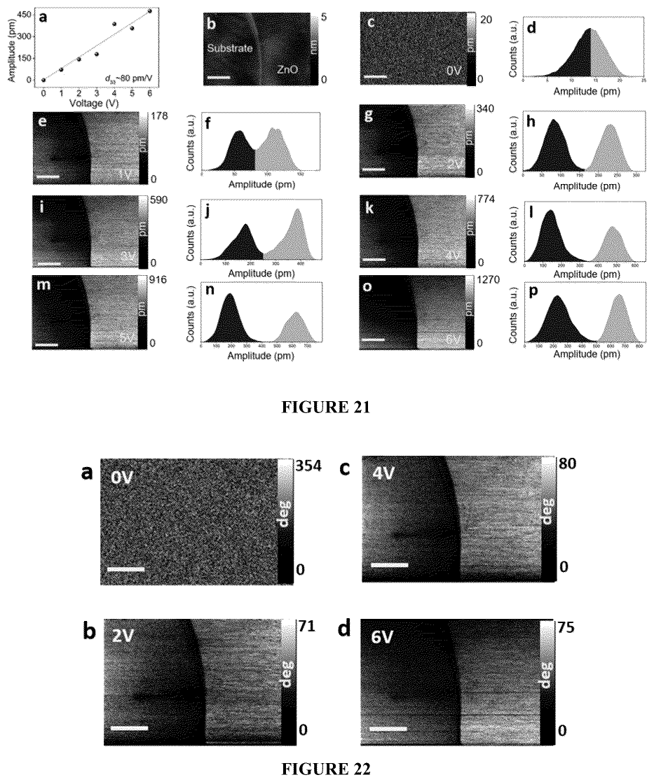

Piezoresponse force microscopy (PFM) was employed to investigate the out-of-plane piezoelectricity of the as-synthesized approximately 1.1 nm ZnO sheets by analyzing the strong coupling between the polarization and the consequent mechanical displacement. The direct piezoelectric effect is the strain causing a polarization, however, because an electric field induces the strain, this is referred to as the converse piezoelectric effect. To measure the vertical piezoelectric response, a conductive probe is used for applying an electric field through the material by a driving voltage between the tip and surface (FIG. 20). Due to a resultant electromechanical coupling, the AFM tip would be deflected due to the periodic surface volume change. Voltages ranging from 0 to 6 V were applied through the tip onto the sample in order to study the out-of-plane or vertical electromechanical response of the ultrathin sheets. The vertical out-of-plane piezoelectric response was measured for various thickness of extra-large ZnO sheets as shown in FIGS. 21-24, delineating exceptional performance and an interesting mechanism.

FIG. 21a illustrates the slope of the average variation in amplitude versus the applied potential, delving the piezoelectric coefficient d₃₃ of the ZnO sheets quantitatively as 80±0.8 pm/V, which is about 4 times larger than the best reported values of d₃₃ for ZnO sheets and 8 times higher than bulk ZnO (Table 1). As the driving voltage increases resulting in a higher electric field being applied, a linear increase in displacement was observed, characteristic of a piezoelectric response. The vertical piezoresponse amplitude profiles for the approximately 1.1 nm (two-unit cells) thin sheets of ZnO (topographic, FIG. 21b) under different driving voltages ranging from 0 to 6 V are shown in FIG. 21c-p along with the statistical distribution of amplitude across the sheets for average values. No PFM amplitude was observed across the ZnO sheets in the absence of electric field as indicated by the PFM response at 0 V.

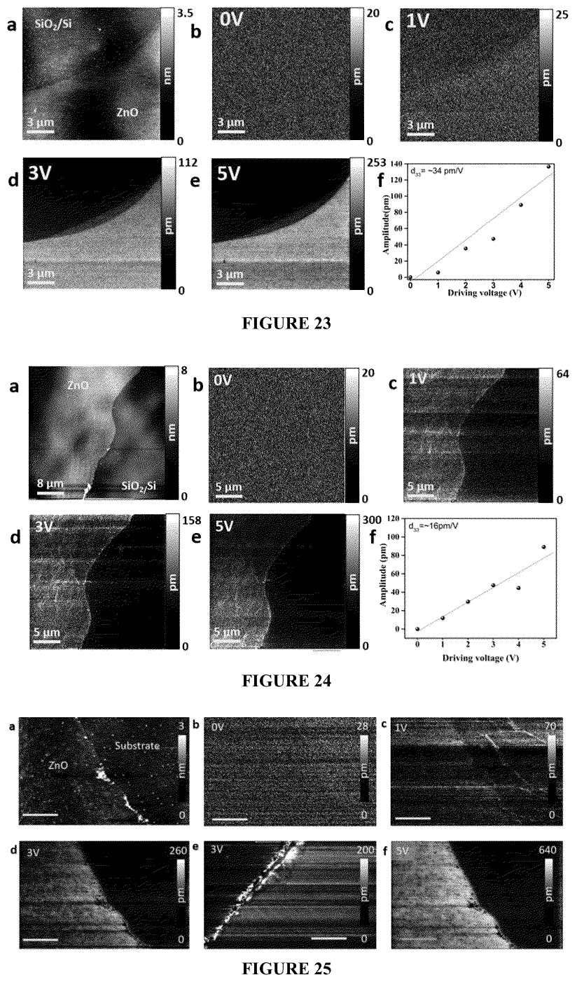

As the DFT calculations in FIGS. 3 and 5a indicate the enhanced piezoresponse can be attributed to changes in the local polarization due to structural alterations in the material. Because of the limited number of atoms and bonds in 2D structures, any disruption in the crystal structure causes a dominant effect. In addition, the bandgap increases which effectively lowers the free carrier concentration. The exceptional performance observed in approximately 1.1 nm thin ZnO sheets motivated us to explore further thinner sheets with half-nanometre thickness. A piezoresponse of approximately 0.6 nm for thin ZnO sheets was also measured and is likely associated with one and half unit-cells (FIG. 23). Surprisingly, a smaller coefficient value (d₃₃=34 pm/V) was obtained from the slope of the average variation in amplitude versus applied potential for approximately 0.6 nm thin sheets of ZnO, thus showing a decrease in the piezoelectricity with a reduction in sheet thickness from 80 to 34 pm/V.

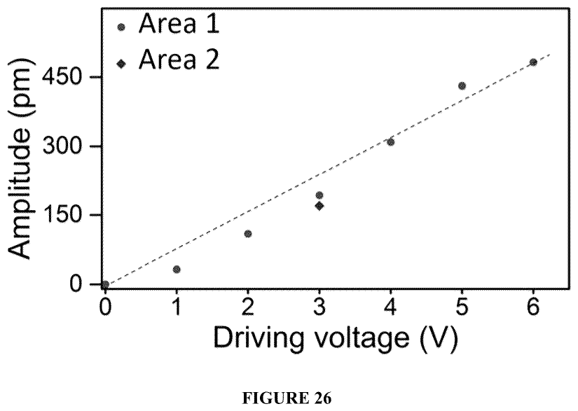

Furthermore, the piezoresponse of various thicknesses of ZnO sheets, ranging from approximately 0.6 to 4 nm, were measured and compared with bulk ZnO (FIG. 5b). This relationship shows an increase in piezoresponse with decreasing thickness from bulk to approximately 1.1 nm, while a further reduction in thickness to half-nanometre resulted in a decreased piezoresponse. As per the DFT analysis presented at the initial part of this section, the covalent interactions with the substrate introduces exceptionally high polarization and asymmetry, resulting in an unprecedented piezoelectric performance for approximately 1.1 nm thin sheets much larger than that of the ZnO bulk. Furthermore, to confirm the reliability of the developed method in producing similar structures of ZnO and reproducibility of the results, PFM measurements were conducted on another approximately 1.1 nm thick ZnO sheet at a different crystal orientation as shown in FIG. 25. A similar value of the d₃₃ coefficient i.e. 78 pm/V was obtained, confirming the high reproducibility of the developed method, FIG. 26. Moreover, similar PFM results on this same sheet after sixteen weeks, confirmed the high stability of the as-synthesized ZnO sheets (FIGS. 25 and 26) and also confirming the monocrystallinity and long-term stability of the ZnO sheets.

TABLE 1
Comparative summary of piezoelectric coefficients

| | | | Measured d₃₃ | |
|---|---|---|---|---|
| | | Thickness | piezocoefficient | |
| Material | Structure | (nm) | (pm/V) | Ref. |
| MoS₂ | Nanosheets | 0.7 | 1.35 ± 0.24 | Prior art |
| MoSSe | Nanosheets | 1.4 | 5.24 | Prior art |
| WSSe | Nanosheets | 1.4 | 5.31 | Prior art |
| α-GaPO₄ | Nanosheet | 1.1 | 7.5 ± 0.8 | Prior art |
| CdS | Bulk | Bulk | 9.71 | Prior art |
| | Nanosheet | 2-3 | 32.8 | Prior art |
| ZnO | Bulk | Bulk | 12.4 | Prior art |
| | Ultrathin sheet | 2-3 | 21.5 ± 1.5 | Prior art |
| | | | 23.7 | |
| | Nanobelt | 65 | 14-26 | Prior art |
| | Ultrathin sheet | ~1.1 | 80 ± 0.8 | This |
| | | | | work |

1. A process for preparing a metal oxide nano sheet, comprising the steps of:
a) heating a metal that is provided on a supporting substrate to a temperature effective to melt the metal to generate a liquid metal film on the supporting substrate,
b) contacting the liquid metal film with an oxygen atmosphere to generate a metal oxide surface layer on the liquid metal film, and
c) contacting the metal oxide surface layer with a target substrate, and exfoliating the metal oxide surface layer from the supporting substrate to form a metal oxide nanosheet layer on the target substrate.

2. The process of claim 1, wherein the metal is heated in the oxygen atmosphere and the metal oxide surface layer is generated in-situ on the liquid metal film.

3. The process of claim 1 or claim 2, wherein the oxygen atmosphere is a controlled oxygen atmosphere provided by an enclosed reaction chamber comprising one or more inlets and one or more outlets, wherein a continuous flow of an inert carrier gas and oxygen flows through at least one inlet and exits through at least one outlet to provide the controlled oxygen atmosphere.

4. The process of claim 3, wherein the controlled oxygen environment has an oxygen concentration of between about 0.1 vol. % to about 10 vol. %.

5. The process of any one of claims 1 to 4, wherein the supporting substrate is heated to a temperature effective to melt the metal to form the liquid metal film on the supporting substrate.

6. The process of claim 5, wherein the supporting substrate is heated to a temperature of between about 200° C. to about 700° C.

7. The process of any one of claims 1 to 6, wherein the supporting substrate comprises an inert material which does not react with the liquid metal film.

8. The process of claim 7, wherein, the supporting substrate is selected from the group consisting of glass, quartz, silicon, and indium tin oxide (ITO).

9. The process of any one of claims 1 to 8, wherein after step b) and prior to step c), the metal oxide surface layer is removed from the liquid metal film to expose fresh liquid metal film to the oxygen atmosphere to form a regenerated metal oxide surface layer.

10. The process of claim 9, wherein the metal oxide surface layer is removed by contacting the metal oxide surface layer with a heated glass substrate.

11. The process of any one of claims 1 to 10, wherein the target substrate has a surface comprising terminating oxygen atoms for adhering the metal oxide surface layer to the surface of the target substrate.

12. The process of claim 11, wherein prior to contacting with the metal oxide surface layer, the target substrate is heated to a temperature effective to enhance adhesion to the metal oxide surface layer.

13. The process of claim 12, wherein the supporting substrate and the target substrate are heated to between about 200° C. to about 700° C.

14. The process of any one of claims 1 to 13, wherein the metal oxide surface layer is contacted with a target substrate for a period of time of between about 0.1 second to about 60 seconds prior to exfoliating the metal oxide surface layer from the supporting substrate.

15. The process of any one of claims 1 to 14, wherein the target substrate comprises an inorganic oxide selected from the group consisting of alumina, silica, ceria, zirconia, and titania.

16. The process of any one of claims 1 to 15, wherein exfoliating the metal oxide surface layer from the supporting substrate exposes fresh liquid metal film to the oxygen atmosphere to form a regenerated metal oxide surface layer.

17. The process of claim 16, further comprising a step of contacting the regenerated metal oxide surface layer with the metal oxide nanosheet layer, and exfoliating the regenerated metal oxide surface layer from the supporting substrate to form a multilayered metal oxide nanosheet.

18. The process of any one of claims 1 to 17, wherein the liquid metal film is a portion of a liquid metal droplet comprising the metal oxide surface layer.

19. The process of claim 18, wherein the liquid metal droplet has an average diameter of between about 0.1 cm to about 10 cm.

20. The process of claim 18 or claim 19, wherein the target substrate is contacted with the metal oxide surface layer at an angle of contact of between about 20° to about 70° with reference to supporting substrate.

21. The process of any one of claims 1 to 20, wherein at least 50% of the surface area of the target substrate is contacted with the metal oxide surface layer.

22. The process of any one of claims 1 to 21, wherein the metal oxide nanosheet has an average axial thickness along the c-axis of between 0.1 nm to about 100 nm.

23. The process of any one of claims 1 to 22, wherein the metal is not an alloy.

24. The process of any one of claims 1 to 23, wherein the metal is zinc metal, the liquid metal film is a liquid zinc film, the metal oxide surface layer is a zinc oxide surface layer, and the metal oxide nanosheet is a zinc oxide nanosheet.

25. The process of claim 24, wherein the zinc oxide nanosheet has an axial thickness along the c-axis of between about 0.1 nm to about 100 nm.

26. The process of claim 24 or claim 25, wherein the zinc oxide nanosheet comprises between about 1 to 100 Zn—O layers.

27. The process of any one of claims 24 to 26, wherein the zinc oxide nanosheet is characterised by an X-ray powder diffraction (XRD) pattern comprising one or more principal peaks located at about 34.4, 36.3, and 47.5 degrees 2θ.

28. The process of any one of claims 24 to 27, wherein the zinc oxide nanosheet has a piezoelectric coefficient d₃₃ of between 20 pm/V to about 120 pm/V.

29. The process of any one of claims 1 to 28, further comprising a step of delaminating the metal oxide nanosheet from the target substrate to obtain a discrete metal oxide nanosheet.

30. The process of any one of claims 1 to 29, further comprising the step of preparing a piezoelectric generator or sensor comprising the metal oxide nanosheet layer.

31. A metal oxide nanosheet prepared by the process of any one of claims 1 to 29.

32. A piezoelectric generator or sensor comprising a metal oxide nanosheet of claim 31.
